(19) United States
(12) Patent Application Publication
(10) Pub. No.: US 2024/0260450 A1
(43) Pub. Date: Aug. 1, 2024

(54) ORGANIC ELECTROLUMINESCENT MATERIALS AND DEVICES

(71) Applicant: Universal Display Corporation, Ewing, NJ (US)

(72) Inventors: Jason BROOKS, Philadelphia, PA (US); Glenn MORELLO, Pittsburgh, PA (US); Chuanjun XIA, Lawrenceville, NJ (US); Jun DENG, Murrysville, PA (US)

(73) Assignee: Universal Display Corporation, Ewing, NJ (US)

(21) Appl. No.: 18/422,601

(22) Filed: Jan. 25, 2024

Related U.S. Application Data
(63) Continuation of application No. 16/456,894, filed on Jun. 28, 2019, now Pat. No. 11,917,902.
Application No. 16/456,894 is a division of application No. 15/067,536, filed on Mar. 11, 2016, now Pat. No. 10,388,894.
Application No. 15/067,536 is a division of application No. 13/787,169, filed on Mar. 6, 2013, now Pat. No. 9,312,505.
(60) Provisional application No. 61/705,400, filed on Sep. 25, 2012.

(51) Int. Cl. H10K 85/30; C07F 15/00; C09K 11/02; C09K 11/06; H10K 50/00; H10K 85/60; H10K 50/11; H10K 50/12; H10K 50/81; H10K 50/82; H10K 101/10

(52) U.S. Cl. CPC H10K 85/346; C07F 15/0086; C09K 11/025; C09K 11/06; H10K 50/00; H10K 85/6572; H10K 85/6576; C09K 2211/1007; C09K 2211/1029; C09K 2211/1033; C09K 2211/1044; C09K 2211/185; H10K 50/11; H10K 50/121; H10K 50/81; H10K 50/82; H10K 85/342; H10K 2101/10

(57) ABSTRACT

Novel organometallic complexes having a structure of Formula (VI)

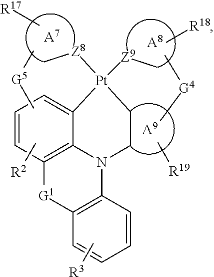

that are useful in organic light emitting devices are disclosed.

### CROSS-REFERENCE TO RELATED APPLICATIONS

This application is a continuation of U.S. patent application Ser. No. 16/456,894, filed Jun. 28, 2019, which is a divisional of U.S. patent application Ser. No. 15/067,536, filed Mar. 11, 2016, now U.S. Pat. No. 10,388,894, which is a division of U.S. patent application Ser. No. 13/787,169, filed Mar. 6, 2013, now U.S. Pat. No. 9,312,505, which claims priority to U.S. Provisional Application Ser. No. 61/705,400, filed Sep. 25, 2012, the entire contents of which are incorporated herein by reference.

### FIELD OF THE INVENTION

The present invention relates to organic light emitting devices (OLEDs). In particular, the invention relates to metal complexes having a bridged N,N-diaryl ligand and their use in various devices, including OLEDs.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

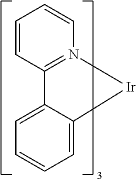

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

In at least one aspect, the invention provides metal complexes having an N,N-diaryl ligand, such as compounds having Formula (I):

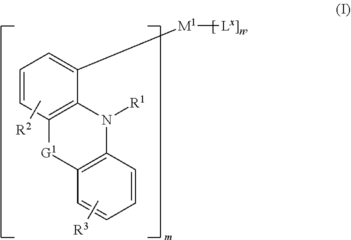

wherein each L^{x} is independently a monodentate ligand, and any two adjacent L^{x} may optionally combine to form a bidentate ligand; wherein M¹ is cobalt(I), rhodium(I), iridium(I), nickel(II), platinum(II), palladium(II), silver(III), gold(III), or copper(III); wherein m is a value from 1 to the maximum number of ligands that may be attached to M¹; wherein m+n is the maximum number of ligands that may be attached to M¹; wherein G¹ is O or CR⁴R⁵; wherein R¹ is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof; wherein R² represents mono-, di-, or tri-substitution, wherein each R² is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R² may optionally combine to form a ring, which can be further substituted; wherein R³ represents mono-, di-, tri-, or tetra-substitution, wherein each R³ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R³ may optionally combine to form a ring, which can be further substituted; wherein R⁴ and R⁵ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R⁴ and R⁵ may optionally combine to form a ring, which can be further substituted; wherein R¹ may optionally combine with any R³ to form a ring system, which can be further substituted; wherein any of R⁴ or R⁵ may optionally combine with any R² or R³ to form a ring system, which can be further substituted; and wherein any of R¹, R², or R³ may optionally combine with one or more L^{x} to form a bidentate, tridentate, or tetradentate ligand.

In some embodiments, M¹ is platinum(II), palladium(II), or gold(III). In some other embodiments, M¹ is platinum (II).

In some embodiments, G¹ is O, C(CH₃)₂, or C(C₆H₅)₂.

In some embodiments, the metal complex is a compound having Formula (II):

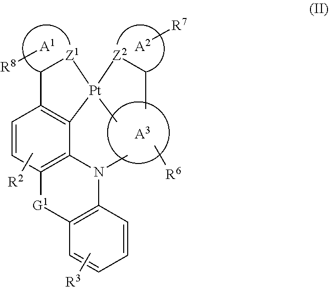

wherein rings A¹, A², and A³ are independently five- or six-membered carbocyclic or heterocyclic aromatic rings having 0-3 nitrogen atoms and 0-1 additional heteroatoms selected from the group consisting of oxygen, sulfur, and selenium; Z₁ and Z₂ are independently carbon or nitrogen; wherein R² represents mono- or di-substitution, wherein each R² is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R² may optionally combine to form a ring, which can be further substituted; wherein R³ represents mono-, di-, tri-, or tetra-substitution, wherein each R³ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R³ may optionally combine to form a ring, which can be further substituted; wherein R⁶ represents mono-, di-, or tri-substitution, wherein each R⁶ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R⁶ may optionally combine to form a ring, which can be further substituted; wherein R⁷ and R⁸ represent mono-, di-, tri-, or tetra-substitution, wherein each R⁷ or R⁸ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R⁷ or any two adjacent R⁸ may optionally combine to form a ring, which can be further substituted; wherein any R³ may optionally combine with any R⁶ to form a ring system, which can be further substituted; wherein any R² may optionally combine with any R⁸ to form a ring system, which can be further substituted; and wherein any R⁶ may optionally combine with any R⁷ to form a ring system, which can be further substituted; wherein any R⁷ may optionally combine with any R⁸ to form a ring system, which can be further substituted. The other variables have the definitions provided in the above embodiments.

In some such embodiments, the metal complex is a compound having Formula (IIa):

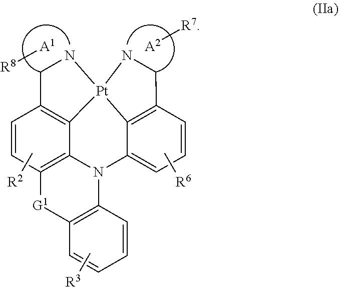

In some other such embodiments, the metal complex is a compound selected from the group consisting of:

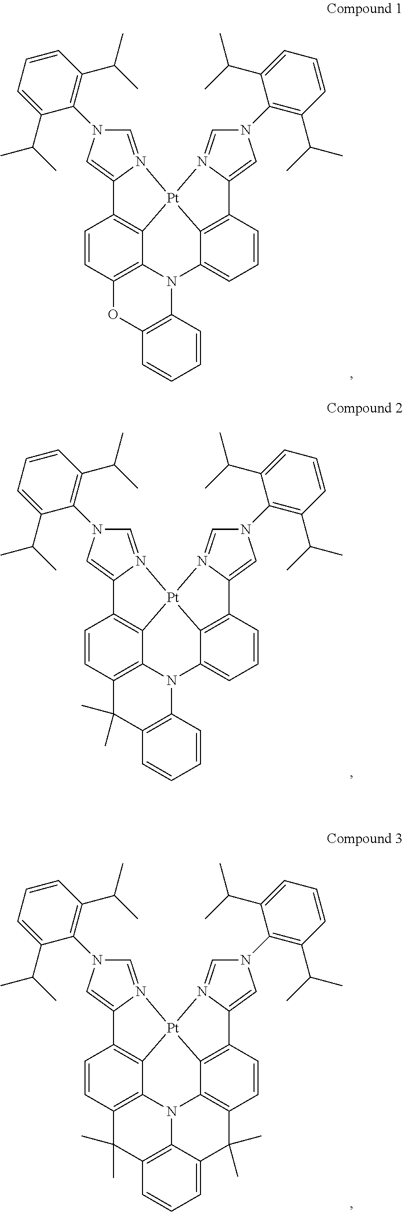

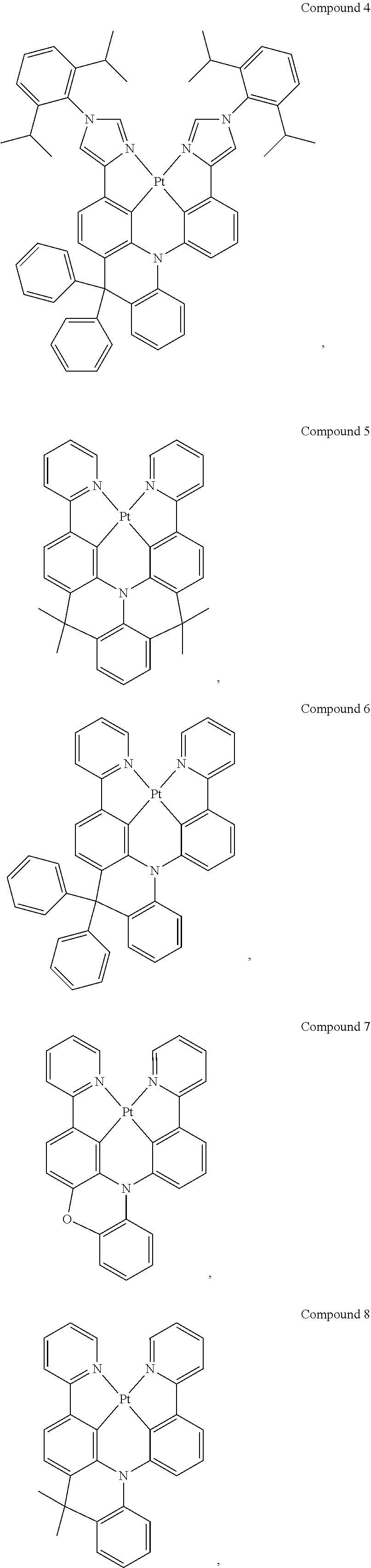

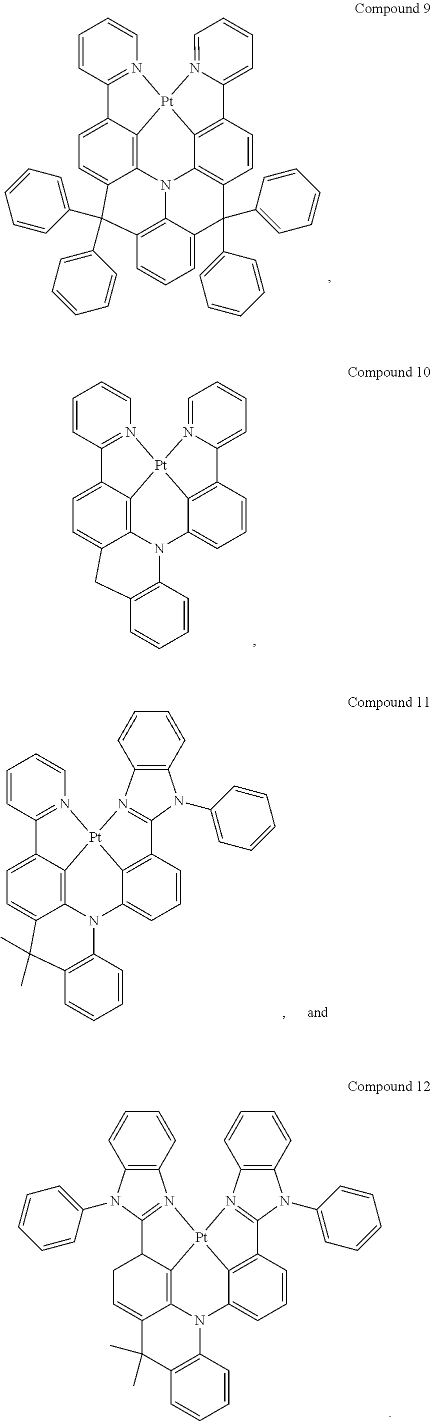

In some embodiments, the metal complex is a compound having Formula (IV):

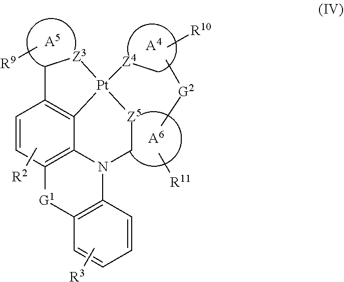

wherein rings A⁴, A⁵, and A⁶ are independently five- or six-membered carbocyc;ic or heterocyclic aromatic rings having 0-3 nitrogen atoms and 0-1 additional heteroatoms selected from the group consisting of oxygen, sulfur, and selenium; wherein Z₃, Z₄, and Z₃ are independently carbon or nitrogen; wherein G² is oxygen, sulfur, CR¹²R^{12a}, SiR¹²R^{12a}, or NR¹²; wherein each R¹² and R^{12a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R¹² and R^{12a} may optionally combine with each other or with any one R¹⁰ or R¹¹ to form a ring system, which can be further substituted; wherein R⁹ and R¹⁰ represent mono-, di-, tri-, or tetra-substitution, wherein each R⁹ or R¹⁰ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R⁹ or any two adjacent R¹⁰ may optionally combine to form a ring, which can be further substituted; wherein R¹¹ represents mono-, di-, or tri-substitution, wherein each R¹¹ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹¹ may optionally combine to form a ring, which can be further substituted; wherein any R³ may optionally combine with any R¹¹ to form a ring system, which can be further substituted; and wherein any R² may optionally combine with any R⁹ to form a ring system, which can be further substituted. The other variables have the definitions provided in the above embodiments.

In some such embodiments, the metal complex is a compound having Formula (IVa):

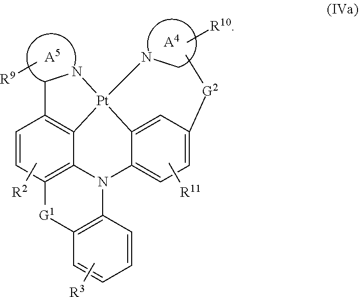

In some embodiments where the metal complex has a Formula (IV) or Formula (IVa), G² is NR¹², and R¹² is phenyl.

In some other embodiments, the metal complex is a compound selected from the group consisting of:

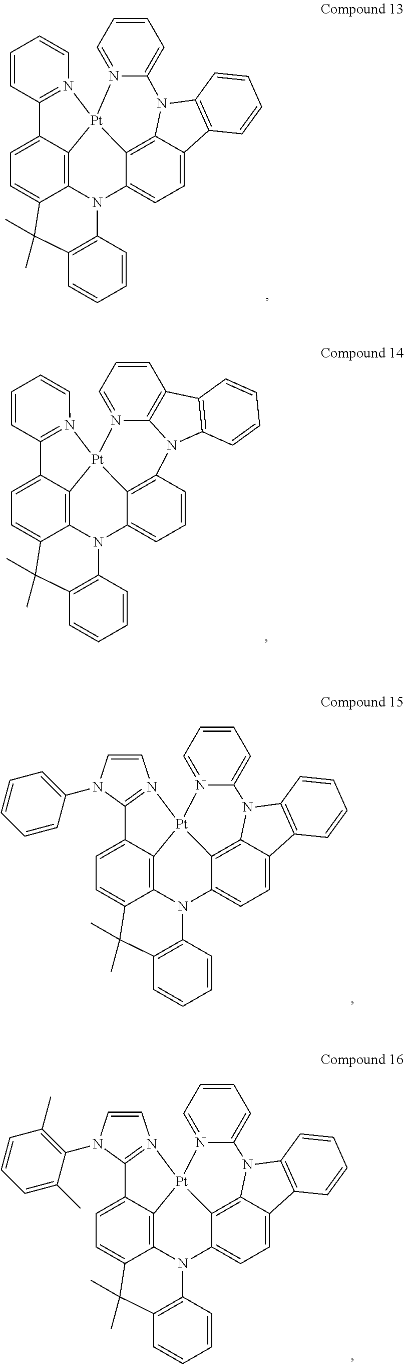

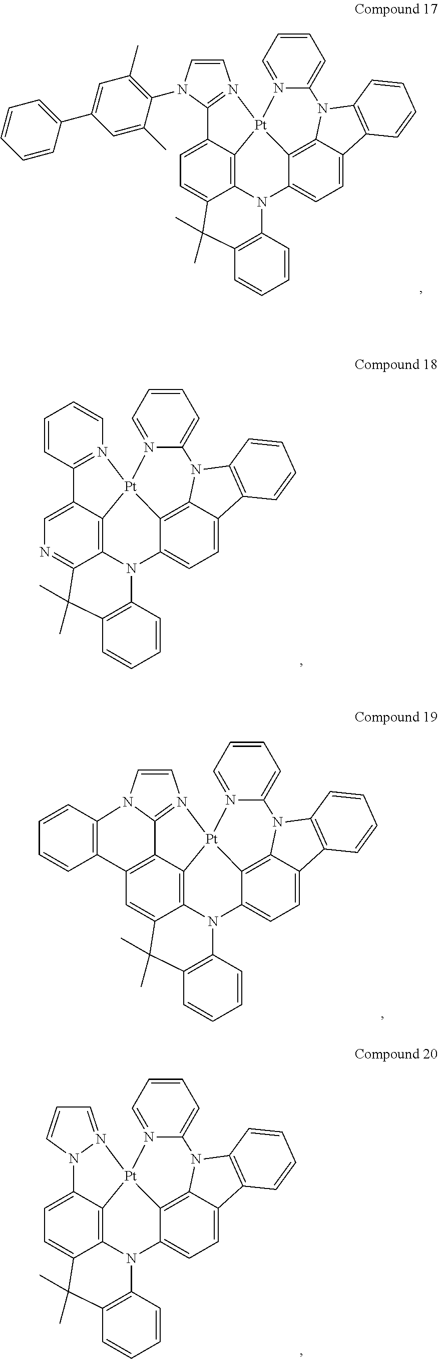

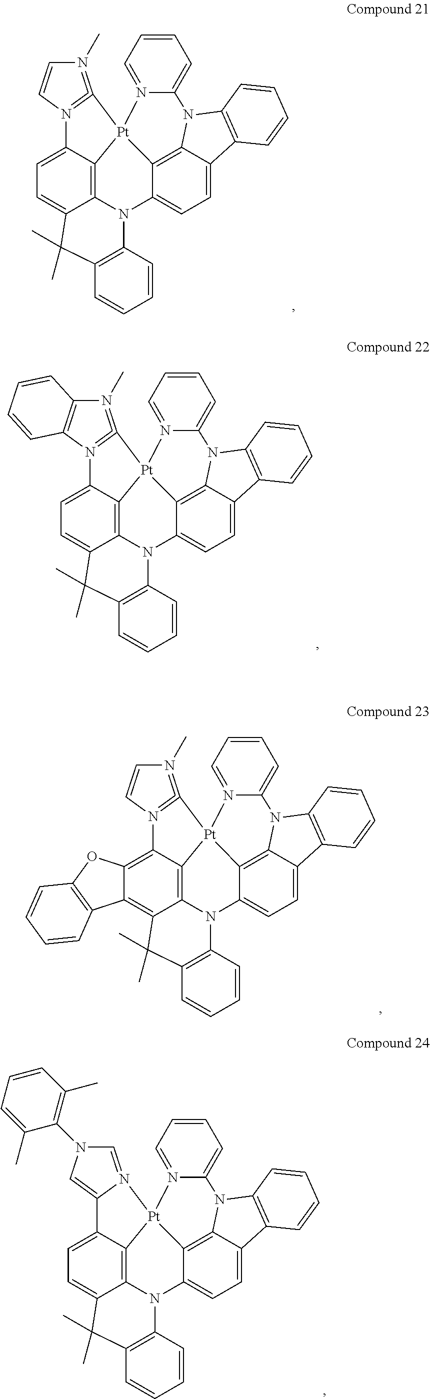

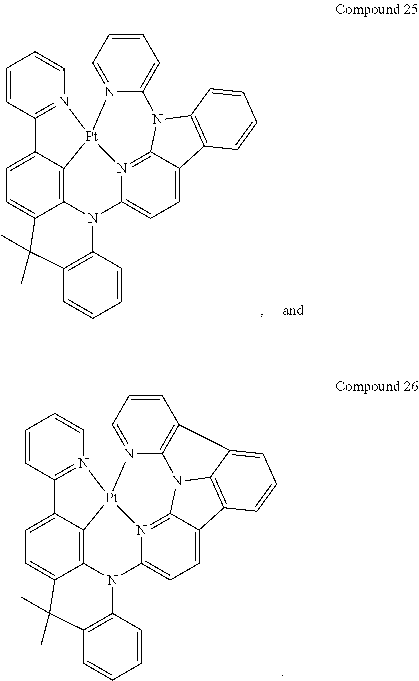

In some embodiments, the metal complex is a compound having Formula (V):

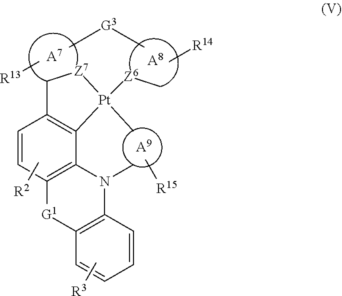

wherein rings A⁷, A⁸, and A⁹ are independently five- or six-membered carboyclic or heterocyclic aromatic rings having 0-3 nitrogen atoms and 0-1 additional heteroatoms selected from the group consisting of oxygen, sulfur, and selenium; wherein Z₆ and Z₇ independently are carbon or nitrogen; G³ is oxygen, sulfur, CR¹⁶R^{16a}, SiR¹⁶R^{16a}, or NR¹⁶; wherein each R¹⁶ and R^{16a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R¹⁶ and R^{16a} may optionally combine with each other or with any one R¹³ or R¹⁴ to form a ring system, which can be further substituted; wherein R¹³ and R¹⁴ represent mono-, di-, or tri-substitution, wherein each R¹³ or R¹⁴ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹³ or any two adjacent R¹⁴ may optionally combine to form a ring, which can be further substituted; wherein R¹⁵ represents mono-, di-, tri- or tetra-substitution, wherein each R¹⁵ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹⁵ may optionally combine to form a ring, which can be further substituted; wherein any R² may optionally combine with any R¹³ to form a ring system, which can be further substituted; and wherein any R¹⁴ may optionally combine with any R¹⁵ to form a ring system, which can be further substituted. The other variables have the definitions provided in the above embodiments.

In some such embodiments, the metal complex is a compound having Formula (Va):

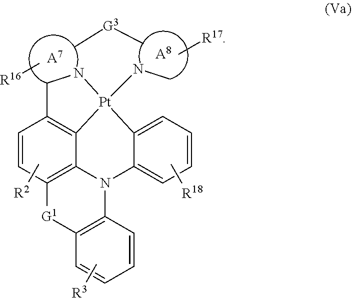

In some embodiments where the metal complex has a Formula (V) or Formula (Va), G³ is NR¹⁶, and R¹⁶ is phenyl.

In some other embodiments, the metal complex is a compound selected from the group consisting of:

“\* MERGEFORMAT \#MERGEFORMAT

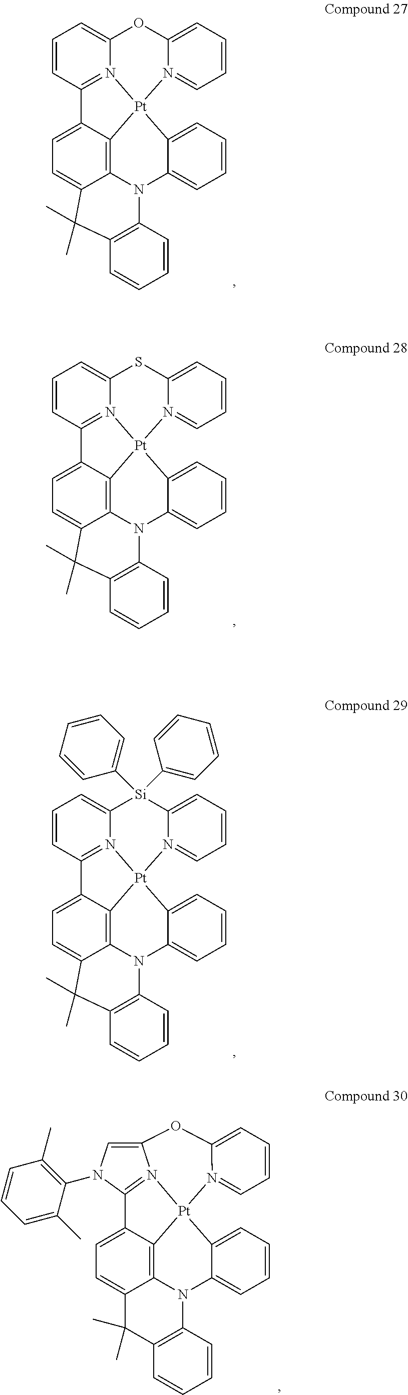

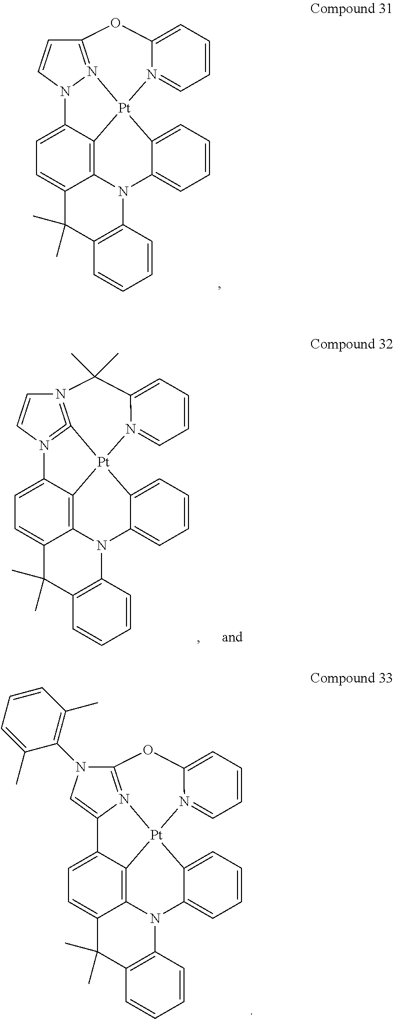

In some embodiments, the metal complex is a compound having Formula (VI):

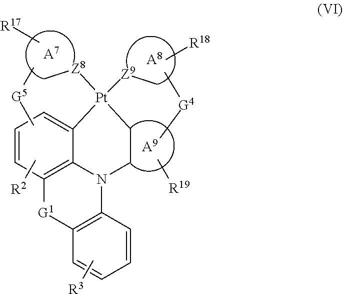

wherein rings A⁷, A⁸, and A⁹ are independently five- or six-membered carbocyc;ic or heterocyclic aromatic rings having 0-3 nitrogen atoms and 0-1 additional heteroatoms selected from the group consisting of oxygen, sulfur, and selenium; wherein Z₈ and Zº are independently carbon or nitrogen; wherein G⁴ is oxygen, sulfur, CR²⁰R^{20a}, SiR²⁰R^{20a}, or NR²⁰; wherein each R²⁰ and R^{20a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R²⁰ and R^{20a} may optionally combine with each other or with any one R¹⁸ or R¹⁹ to form a ring system, which can be further substituted; wherein G⁵ is oxygen, sulfur, CR²¹R^{21a}, SiR²¹R^{21a}, or NR²¹; wherein each R²¹ and R^{21a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R²¹ and R^{21a} may optionally combine with each other or with any one R² or R¹⁷ to form a ring system, which can be further substituted; wherein R¹⁷ and R¹⁸ represent mono-, di-, tri-, or tetra-substitution, wherein each R¹⁷ or R¹⁸ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹⁷ or any two adjacent R¹⁸ may optionally combine to form a ring, which can be further substituted; wherein R¹⁹ represents mono-, di-, or tri-substitution, wherein each R¹⁹ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹⁹ may optionally combine to form a ring, which can be further substituted; wherein any R³ may optionally combine with any R¹⁹ to form a ring system, which can be further substituted. The other variables have the definitions provided in the above embodiments.

In some other embodiments, the metal complex is a compound selected from the group consisting of:

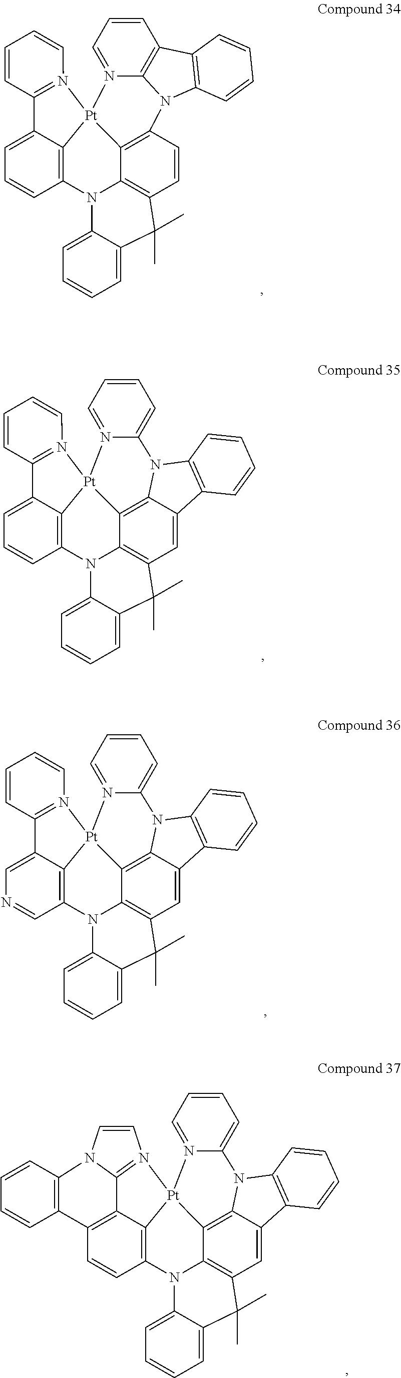

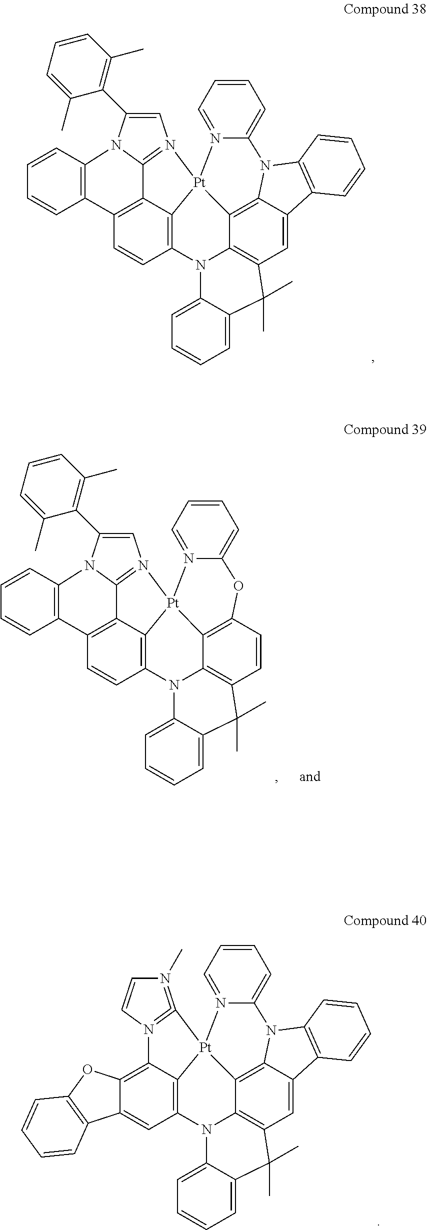

In some embodiments, the metal complex is a compound having Formula (VII):

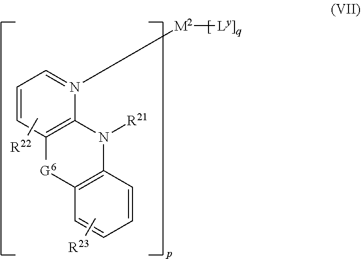

wherein each L^{y} is independently a monodentate ligand, and any two adjacent Lymay optionally combine to form a bidentate ligand; wherein M2 is cobalt(I), rhodium(I), iridium(I), nickel(II), platinum(II), palladium(II), silver(III), gold(III), or copper(III); wherein p is a value from 1 to the maximum number of ligands that may be attached to M²; wherein p+q is the maximum number of ligands that may be attached to M²; wherein G⁶ is O or CR²⁴R²⁵; wherein R²¹ is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof; wherein R²² represents mono-, di-, or tri-substitution, wherein each R²² is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R² may optionally combine to form a ring, which can be further substituted; wherein R²³ represents mono-, di-, tri-, or tetra-substitution, wherein each R²³ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R³ may optionally combine to form a ring, which can be further substituted; wherein R²⁴ and R²⁵ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R²⁴ and R²⁵ may optionally combine to form a ring, which can be further substituted; wherein R²¹ may optionally combine with any R²³ to form a ring system, which can be further substituted; wherein any of R²⁴ or R²⁵ may optionally combine with any R²² or R²³ to form a ring system, which can be further substituted; and wherein any of R²¹, R²², or R²³ may optionally combine with one or more L^{y} to form a bidentate, tridentate, or tetradentate ligand.

In some embodiments, M² is platinum(II), palladium(II), or gold(III). In some other embodiments, M² is platinum (II).

In some embodiments, G⁶ is O, C(CH₃)₂, or C(C₆H₅)₂.

In some other embodiments, the metal complex is a compound selected from the group consisting of:

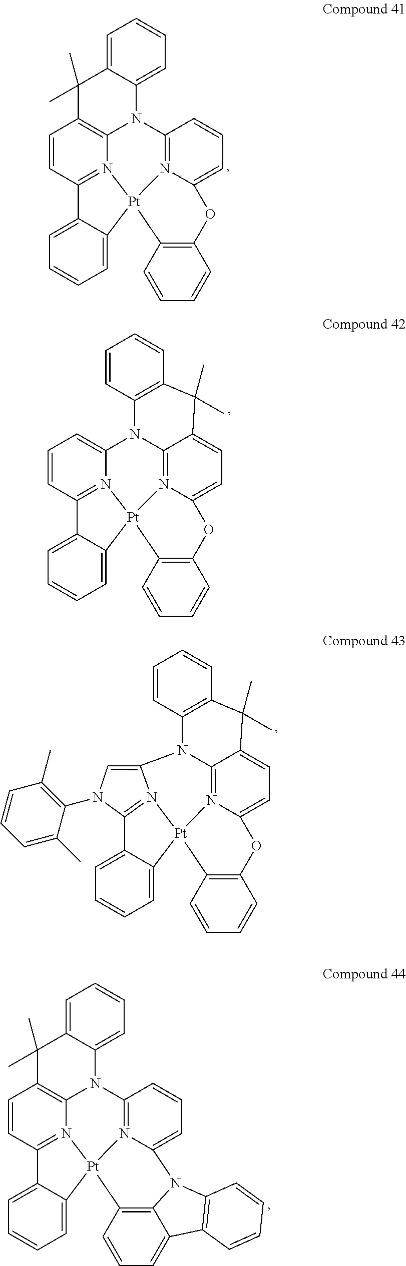

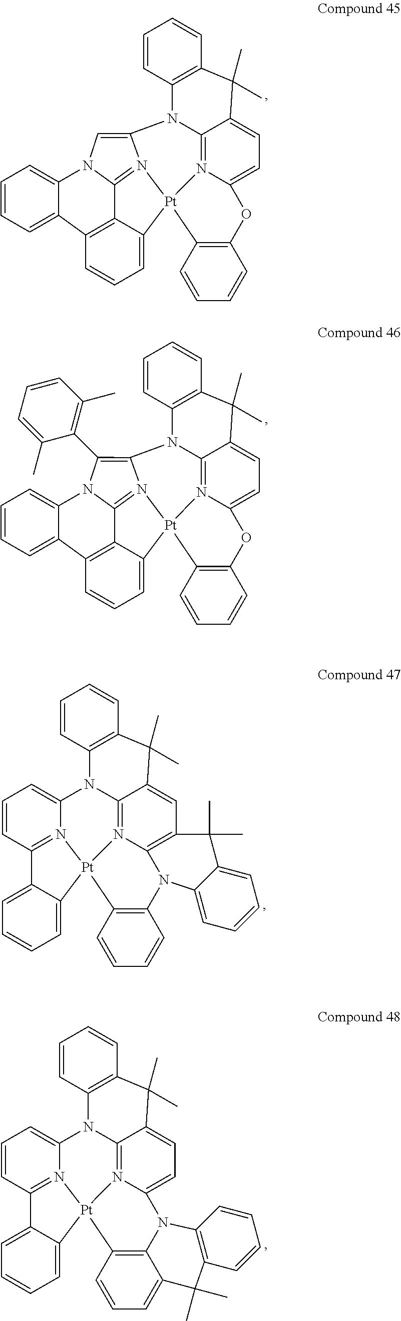

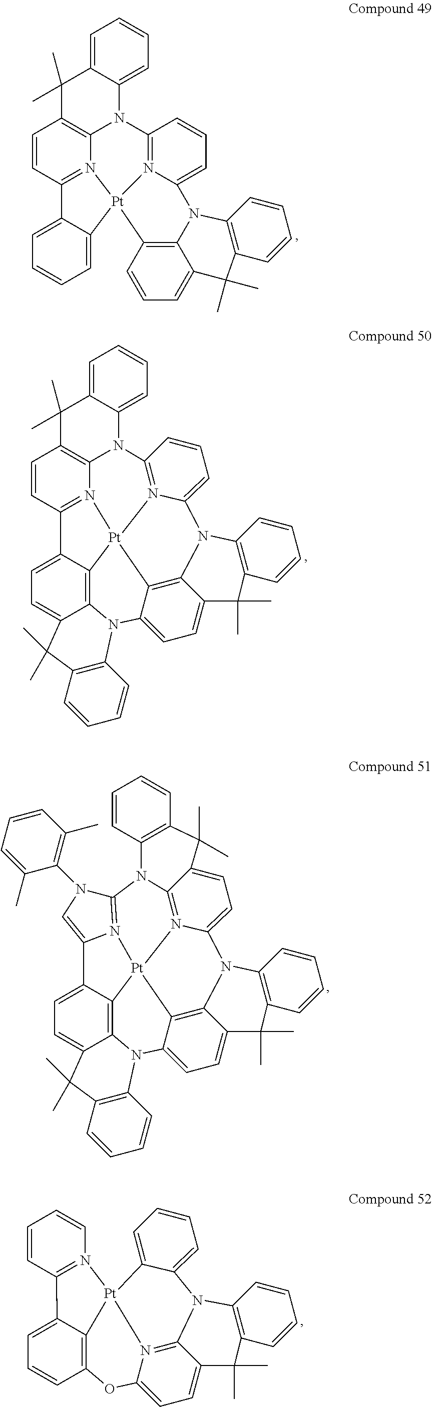

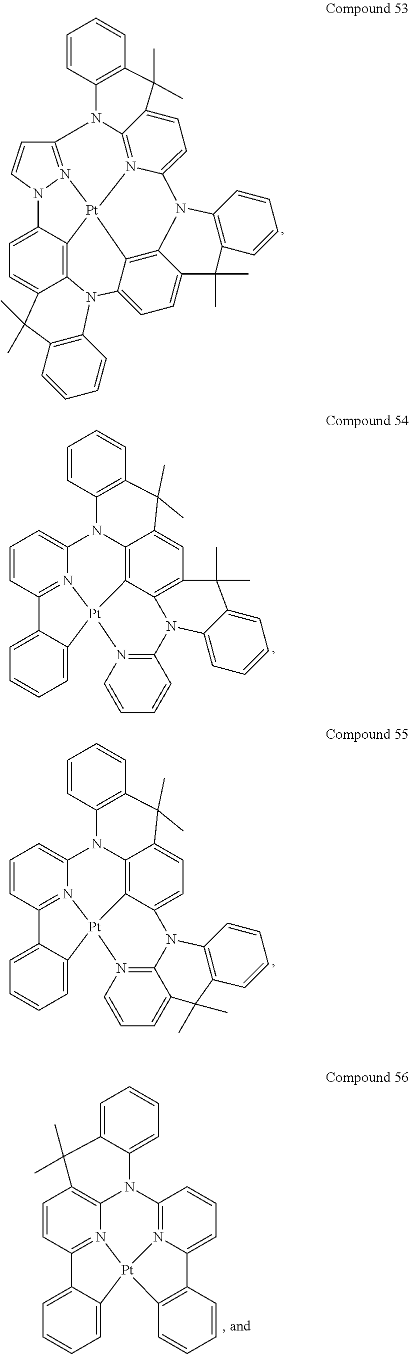

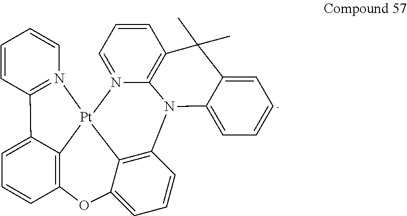

In another aspect, the invention provides devices that include metal complexes having a bridged N,N-diaryl ligand, such as those described in the foregoing paragraphs. In some embodiments, the invention provides a first device comprising a first organic light emitting device, which further comprises: an anode; a cathode; and an organic layer disposed between the anode and the cathode, which comprises a boron-nitrogen heterocycle according to any of the above embodiments. In some embodiments, the first device is a consumer product. In some embodiments, the first device is an organic light emitting device (OLED). In some embodiments, the first device comprises a lighting panel.

In some embodiments, the organic layer of the first device is an emissive layer. In some such embodiments, the emissive layer comprises an emissive dopant. In some embodiments, a metal complex having a bridged N,N-diaryl ligand (as described above) is an emissive dopant. In some other embodiments, a metal complex having a bridged N,N-diaryl ligand (as described above) is a non-emissive dopant.

In some embodiments, the organic layer of the first device comprises a host. In some such embodiments, the host comprises a triphenylene containing benzo-fused thiophene or benzo-fused furan; wherein any substituent in the host is an unfused substituent independently selected from the group consisting of CₙH₂ₙ₊₁, OCₙH₂ₙ₊₁, OAr₁, N(CₙH₂ₙ₊₁)₂, N(Ar₁)(Ar₂), CH═CH—CₙH₂ₙ₊₁, C≡C—CₙH₂ₙ₊₁, Ar₁, Ar₁—Ar₂, and CₙH₂n-Ar₁, or the host has; wherein n is from 1 to 10; and wherein Ar₁ and Ar₂ are independently selected from the group consisting of benzene, biphenyl, naphthalene, triphenylene, carbazole, and heteroaromatic analogs thereof. In some other embodiments, the host comprises a compound selected from the group consisting of: carbazole, dibenzothiophene, dibenzofuran, dibenzoselenophene, azacarbazole, aza-dibenzothiophene, aza-dibenzofuran, and aza-dibenzoselenophene.

In some embodiments, the host is a compound selected from the group consisting of:

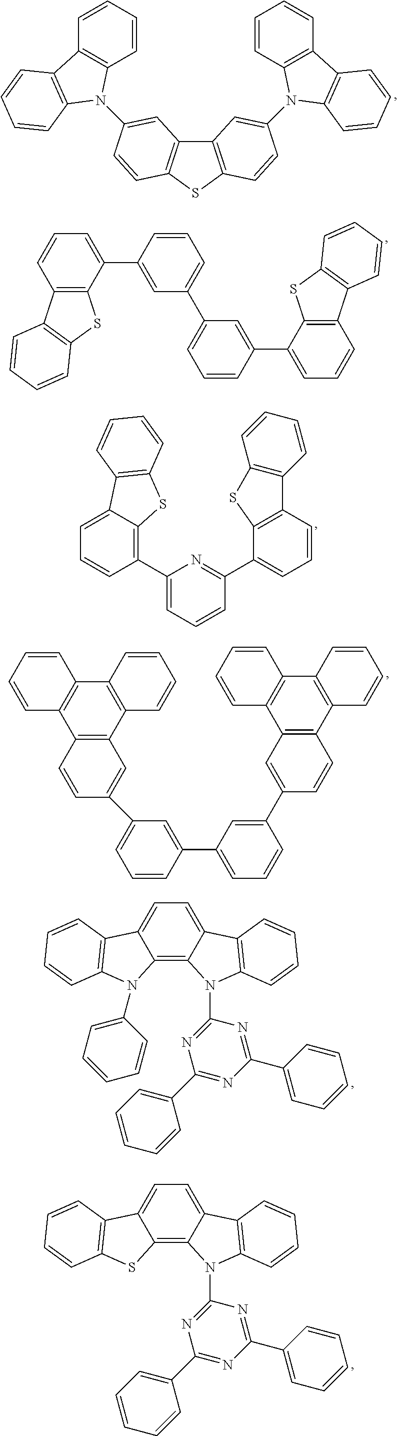

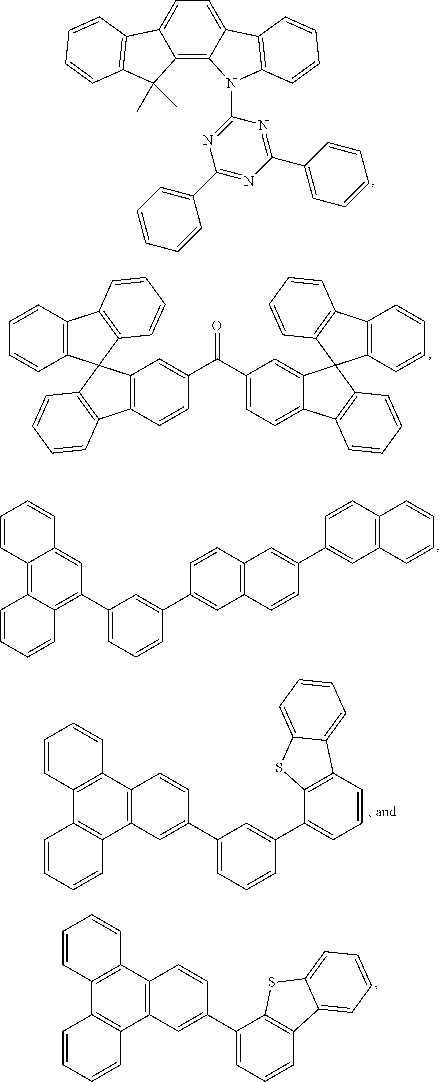

and combinations thereof.

In some embodiments, the host is a metal complex.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an embodiment of a metal complex having a bridged N,N-diaryl ligand.

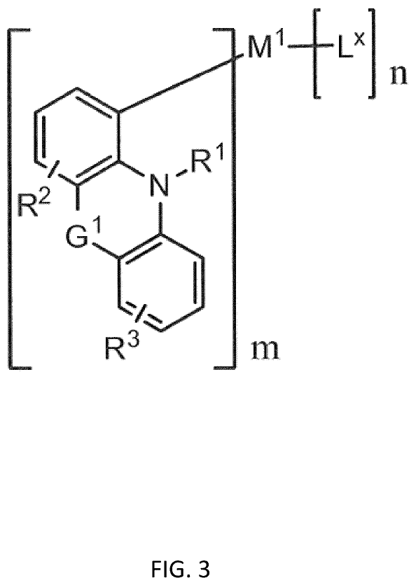

FIG. 4 shows a positive-mode MALDI-TOF mass spectrum for Host 1 and Comparative Example 3. The arrow shows the major fragment, which is the loss of N-phenyl. The inset shows the structure and mass of the bond-broken photoproduct.

FIG. 5 shows a positive-mode MALDI-TOF mass spectrum for Host 1 and Comparative Example 2. The arrow shows the major fragment, which is the loss of N-phenyl. The inset shows the structure and mass of the bond-broken photoproduct.

FIG. 6 shows a positive-mode MALDI-TOF mass spectrum for Host 1 and Comparative Example 1. The arrow shows the major fragment, which is the loss of N-phenyl. The inset shows the structure and mass of the bond-broken photoproduct.

FIG. 7 shows the geometry for Compound 3, which shows the N-phenyl bond intact. The left structure shows the optimized ground state triplet. The right structure shows an optimized N-phenyl bond-breaking triplet. Slight differences in the geometry of the phenyl and germinal dimethyl groups can be seen, which may account for the small calculated energy difference of 5.22 kcal/mol.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

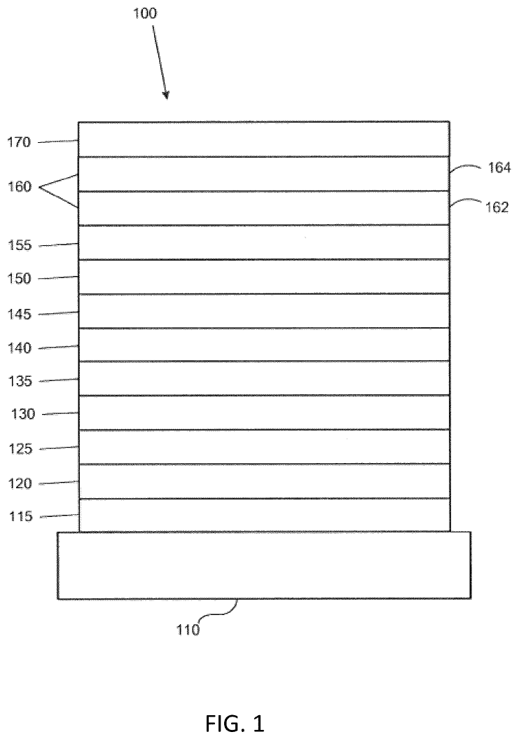

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F.sub.4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

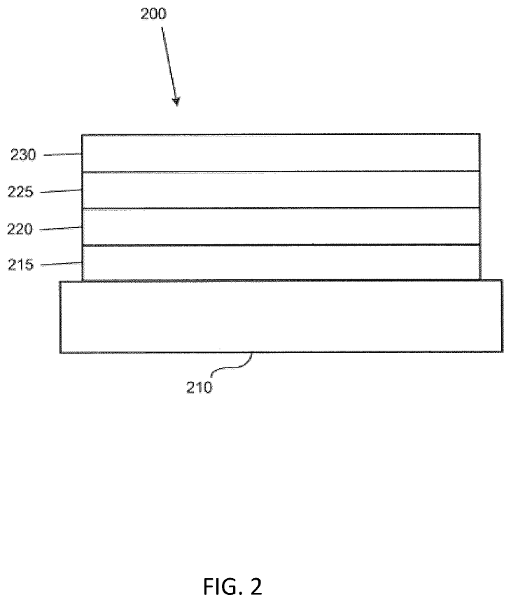

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. patent application Ser. No. 10/233,470, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention may be incorporated into a wide variety of consumer products, including flat panel displays, computer monitors, medical monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.).

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

The terms halo, halogen, alkyl, cycloalkyl, alkenyl, alkynyl, arylkyl, heterocyclic group, aryl, aromatic group, and heteroaryl are known to the art, and are defined in U.S. Pat. No. 7,279,704 at cols. 31-32, which are incorporated herein by reference.

Metal complexes having ligands with N,N-diaryl groups can function as emissive agents, e.g., phosphorescent emitters. In some instances, however, such structures may exhibit instability due to rupture of the N-aryl bond, thereby limiting the utility of such compounds as emissive agents. In some embodiments of the invention, a bridging group is incorporated into the N,N-diaryl ligand structure to stabilize the ligand and strengthen the N-aryl bond. The disclosed bridging structures can also improve the steric properties of the ligand and make it more suitable for certain types of coordination, such as tetradentate coordination in a square planar configuration (e.g., with platinum (II)).

In at least one aspect, the invention provides metal complexes having an N,N-diaryl ligand, such as compounds having Formula (I):

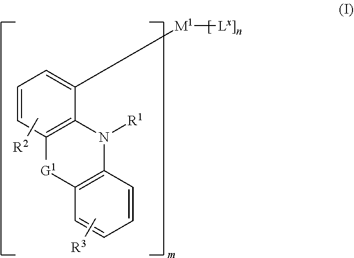

wherein each L^{x} is independently a monodentate ligand, and any two adjacent L^{x} may optionally combine to form a bidentate ligand; wherein M¹ is cobalt(I), rhodium(I), iridium(I), nickel(II), platinum(II), palladium(II), silver(III), gold(III), or copper(III); wherein m is a value from 1 to the maximum number of ligands that may be attached to M¹; wherein m+n is the maximum number of ligands that may be attached to M¹; wherein G¹ is O or CR⁴R⁵; wherein R¹ is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof; wherein R² represents mono-, di-, or tri-substitution, wherein each R² is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R² may optionally combine to form a ring, which can be further substituted; wherein R³ represents mono-, di-, tri-, or tetra-substitution, wherein each R³ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R³ may optionally combine to form a ring, which can be further substituted; wherein R⁴ and R⁵ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R⁴ and R⁵ may optionally combine to form a ring, which can be further substituted; wherein R¹ may optionally combine with any R³ to form a ring system, which can be further substituted; wherein any of R⁴ or R⁵ may optionally combine with any R² or R³ to form a ring system, which can be further substituted; and wherein any of R¹, R², or R³ may optionally combine with one or more L^{x} to form a bidentate, tridentate, or tetradentate ligand.

In some embodiments, M¹ is platinum(II), palladium(II), or gold(III). In some other embodiments, M¹ is platinum (II).

In some embodiments, G¹ is O, C(CH₃)₂, or C(C₆H₅)₂.

In some embodiments, the metal complex is a compound having Formula (II):

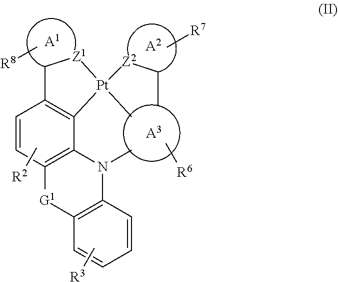

wherein rings A¹, A², and A³ are independently five- or six-membered carbocyclic or heterocyclic aromatic rings having 0-3 nitrogen atoms and 0-1 additional heteroatoms selected from the group consisting of oxygen, sulfur, and selenium; Z₁ and Z₂ are independently carbon or nitrogen; wherein R² represents mono- or di-substitution, wherein each R² is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R² may optionally combine to form a ring, which can be further substituted; wherein R³ represents mono-, di-, tri-, or tetra-substitution, wherein each R³ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R³ may optionally combine to form a ring, which can be further substituted; wherein R⁶ represents mono-, di-, or tri-substitution, wherein each R⁶ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R⁶ may optionally combine to form a ring, which can be further substituted; wherein R⁷ and R⁸ represent mono-, di-, tri-, or tetra-substitution, wherein each R⁷ or R⁸ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R⁷ or any two adjacent R⁸ may optionally combine to form a ring, which can be further substituted; wherein any R³ may optionally combine with any R⁶ to form a ring system, which can be further substituted; wherein any R² may optionally combine with any R⁸ to form a ring system, which can be further substituted; and wherein any R⁶ may optionally combine with any R⁷ to form a ring system, which can be further substituted; wherein any R⁷ may optionally combine with any R⁸ to form a ring system, which can be further substituted. The other variables have the definitions provided in the above embodiments.

In some such embodiments, the metal complex is a compound having Formula (IIa):

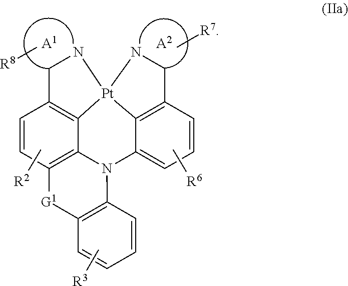

In some other such embodiments, the metal complex is a compound selected from the group consisting of:

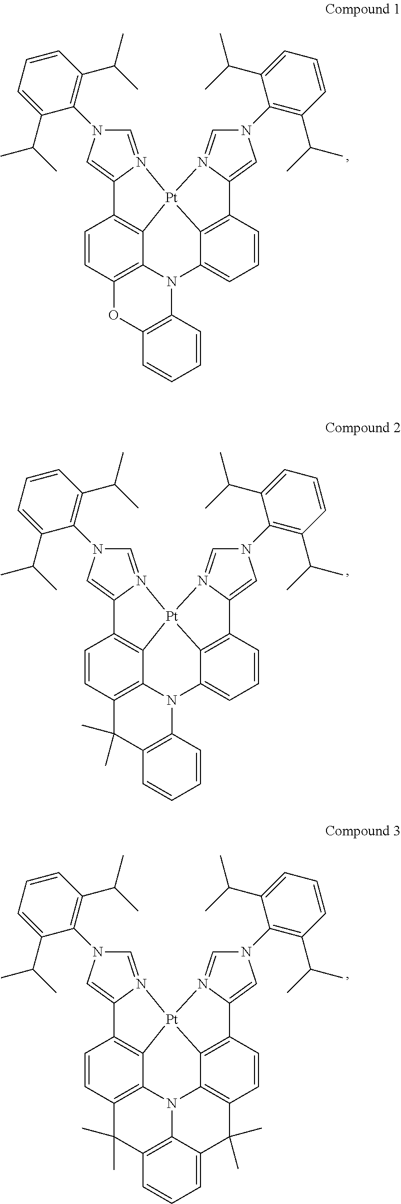

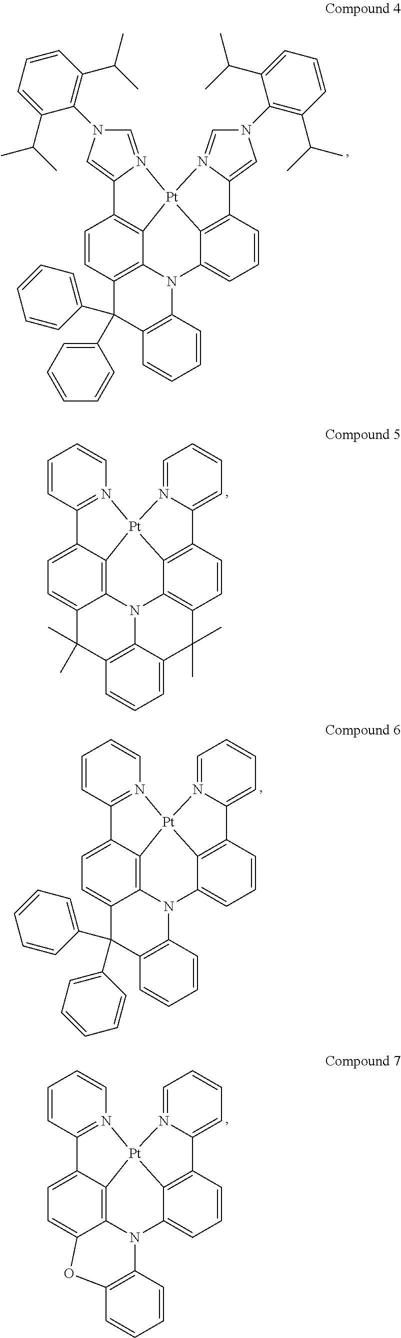

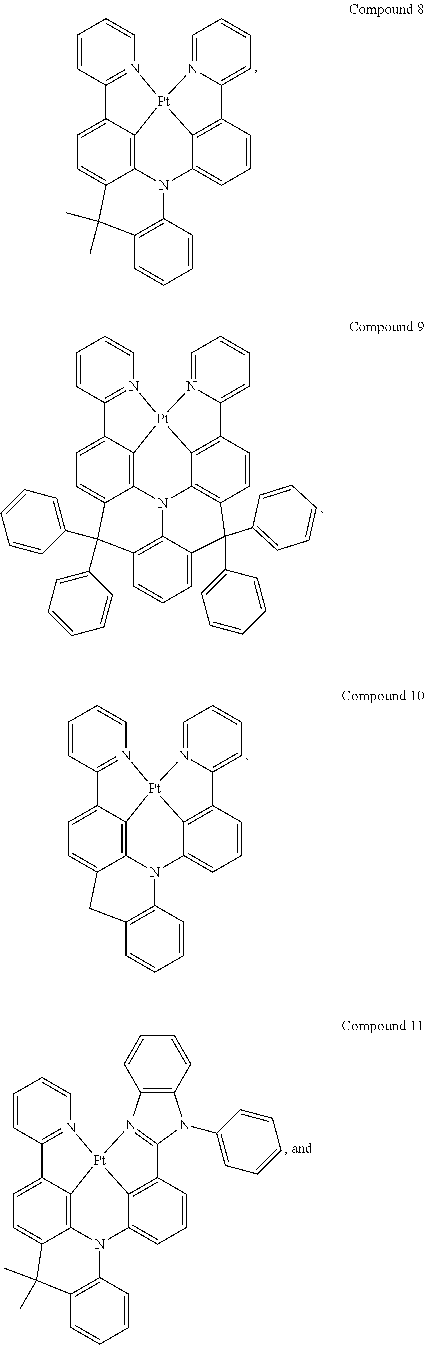

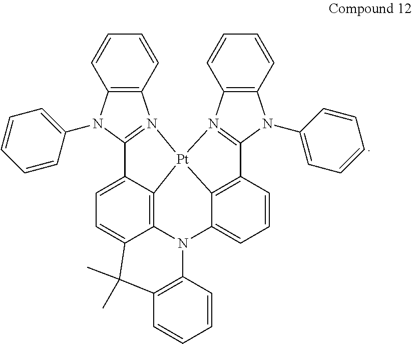

In some embodiments, the metal complex is a compound having Formula (IV):

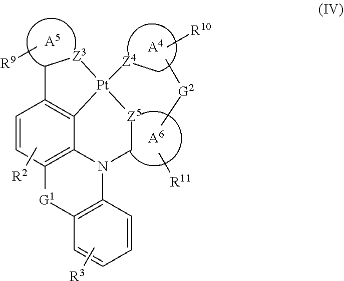

wherein rings A⁴, A⁵, and A⁶ are independently five- or six-membered carbocyc;ic or heterocyclic aromatic rings having 0-3 nitrogen atoms and 0-1 additional heteroatoms selected from the group consisting of oxygen, sulfur, and selenium; wherein Z³, Z⁴, and Z⁵ are independently carbon or nitrogen; wherein G² is oxygen, sulfur, CR¹²R^{12a}, SiR¹² R^{12a}, or NR¹²; wherein each R¹² and R^{12a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R¹² and R^{12a} may optionally combine with each other or with any one R¹⁰ or R¹¹ to form a ring system, which can be further substituted; wherein R⁹ and R¹⁰ represent mono-, di-, tri-, or tetra-substitution, wherein each R⁹ or R¹⁰ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R⁹ or any two adjacent R¹⁰ may optionally combine to form a ring, which can be further substituted; wherein R¹¹ represents mono-, di-, or tri-substitution, wherein each R¹¹ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹¹ may optionally combine to form a ring, which can be further substituted; wherein any R³ may optionally combine with any R¹¹ to form a ring system, which can be further substituted; and wherein any R² may optionally combine with any R′ to form a ring system, which can be further substituted. The other variables have the definitions provided in the above embodiments.

In some such embodiments, the metal complex is a compound having Formula (IVa):

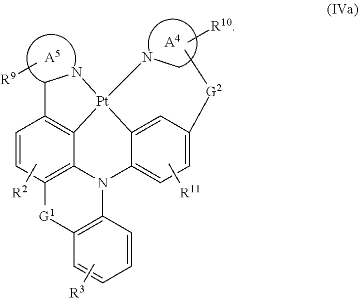

In some embodiments where the metal complex has a Formula (IV) or Formula (IVa), G² is NR¹², and R¹² is phenyl.

In some other embodiments, the metal complex is a compound selected from the group consisting of:

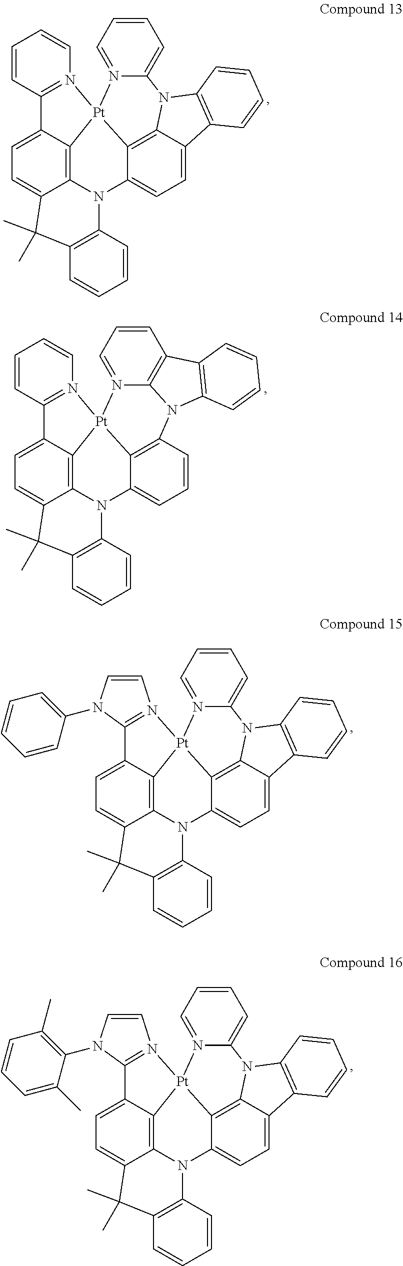

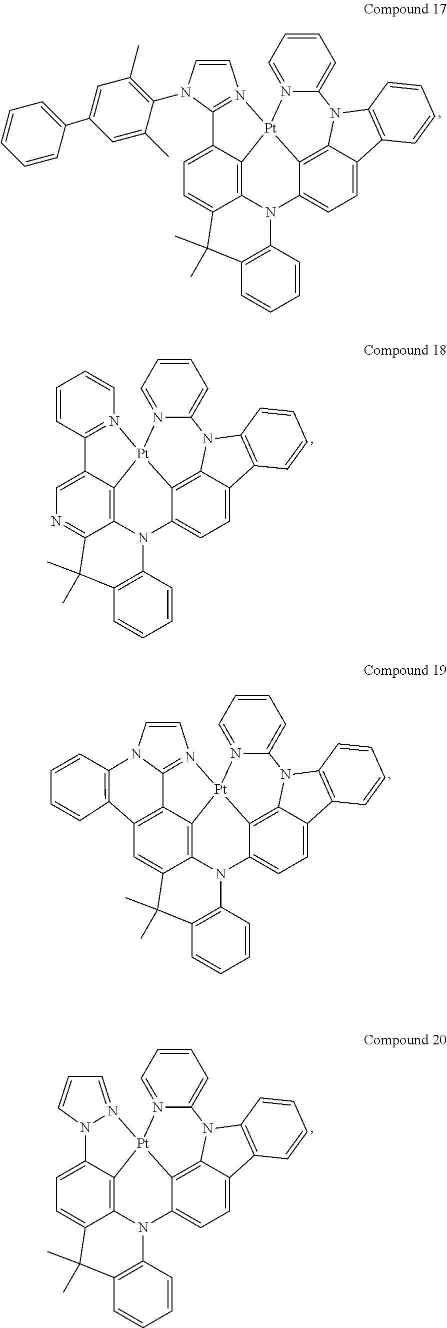

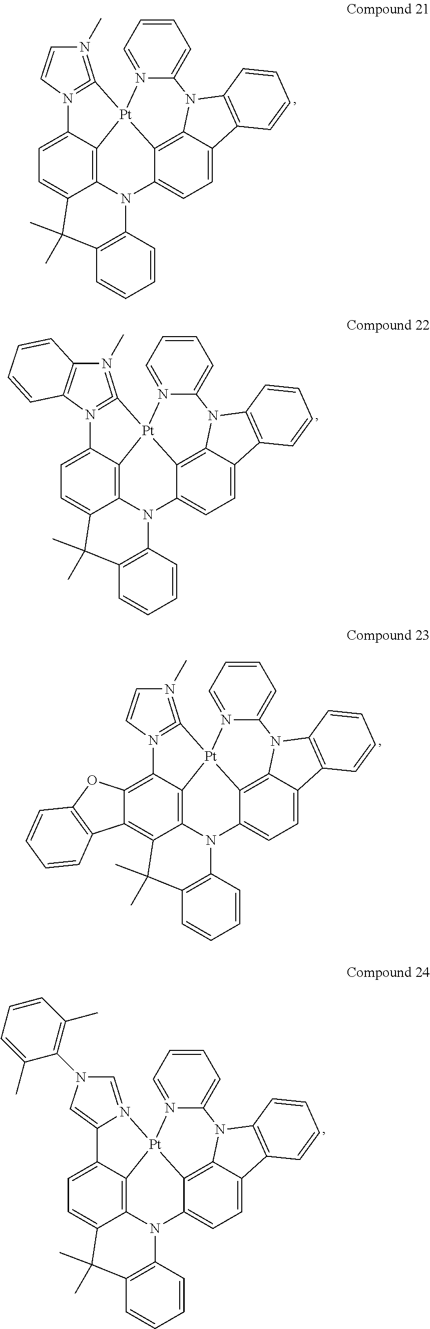

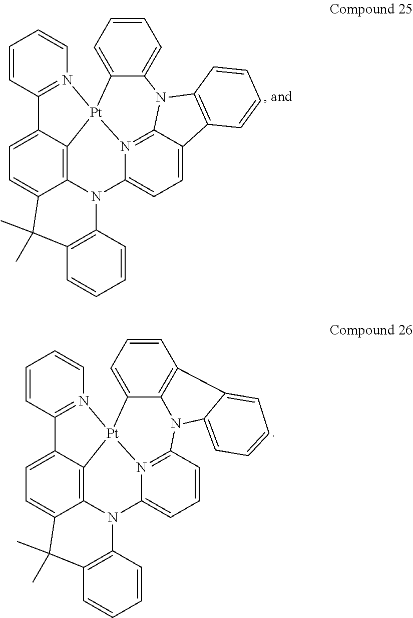

In some embodiments, the metal complex is a compound having Formula (V):

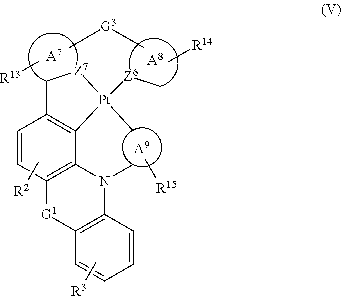

wherein rings A⁷, A⁸, and A′ are independently five- or six-membered carboyclic or heterocyclic aromatic rings having 0-3 nitrogen atoms and 0-1 additional heteroatoms selected from the group consisting of oxygen, sulfur, and selenium; wherein Z⁶ and Z′ independently are carbon or nitrogen; G³ is oxygen, sulfur, CR¹⁶R^{16a}, SiR¹⁶R^{16a}, or NR¹⁶; wherein each R¹⁶ and R^{16a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R¹⁶ and R^{16a} may optionally combine with each other or with any one R¹³ or R¹⁴ to form a ring system, which can be further substituted; wherein R¹³ and R¹⁴ represent mono-, di-, or tri-substitution, wherein each R¹³ or R¹⁴ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹³ or any two adjacent R¹⁴ may optionally combine to form a ring, which can be further substituted; wherein R¹⁵ represents mono-, di-, tri- or tetra-substitution, wherein each R¹⁵ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹⁵ may optionally combine to form a ring, which can be further substituted; wherein any R² may optionally combine with any R¹³ to form a ring system, which can be further substituted; and wherein any R¹⁴ may optionally combine with any R¹⁵ to form a ring system, which can be further substituted. The other variables have the definitions provided in the above embodiments.

In some such embodiments, the metal complex is a compound having Formula (Va):

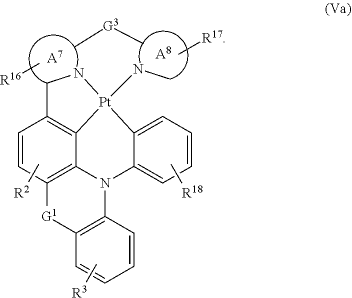

In some embodiments where the metal complex has a Formula (V) or Formula (Va), G³ is NR¹⁶, and R¹⁶ is phenyl.

In some other embodiments, the metal complex is a compound selected from the group consisting of:

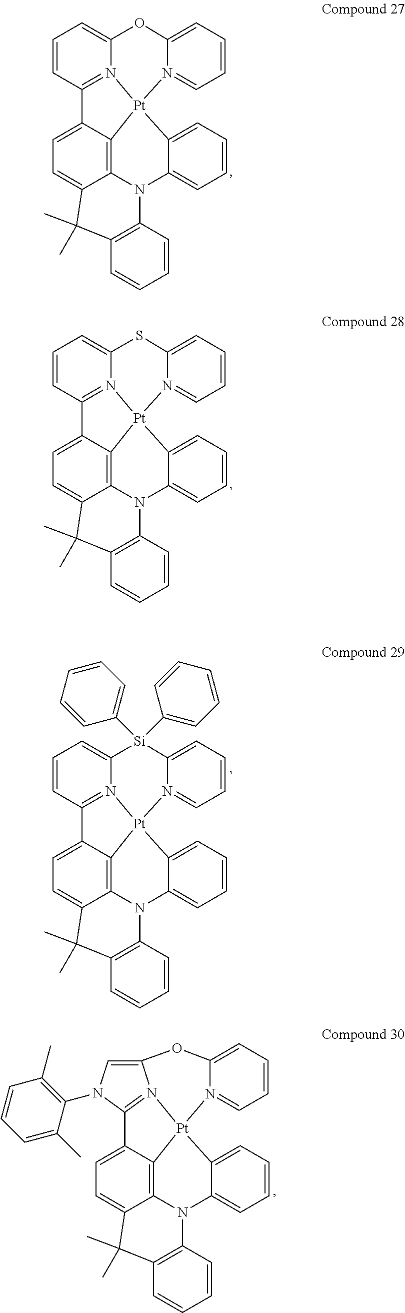

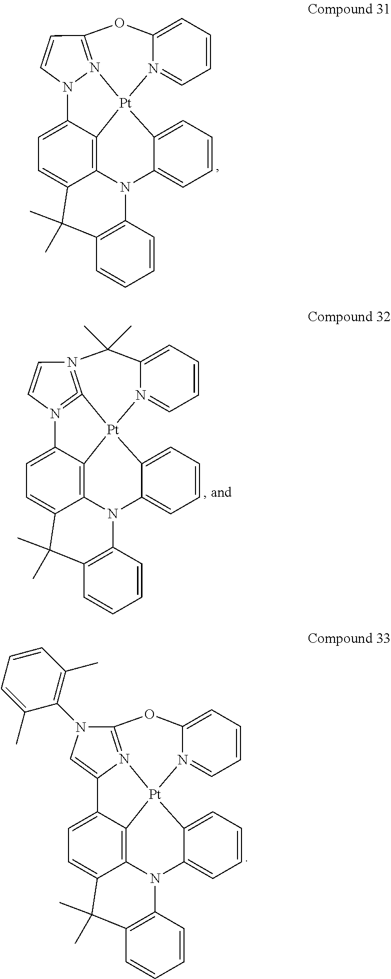

In some embodiments, the metal complex is a compound having Formula (VI):

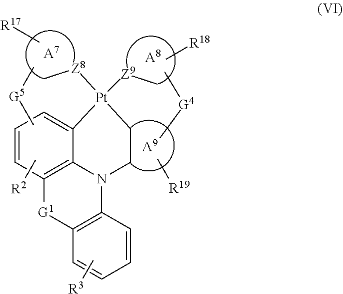

wherein rings A⁷, A⁸, and A⁹ are independently five- or six-membered carbocyc;ic or heterocyclic aromatic rings having 0-3 nitrogen atoms and 0-1 additional heteroatoms selected from the group consisting of oxygen, sulfur, and selenium; wherein Z⁸ and Zº are independently carbon or nitrogen; wherein G⁴ is oxygen, sulfur, CR²⁰R^{20a}, SiR²⁰R^{20a}, or NR²⁰; wherein each R²⁰ and R^{20a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R²⁰ and R^{20a} may optionally combine with each other or with any one R¹⁸ or R¹⁹ to form a ring system, which can be further substituted; wherein G⁵ is oxygen, sulfur, CR²¹R^{21a}, SiR²¹R^{21a}, or NR²¹; wherein each R²¹ and R^{21a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R²¹ and R^{21a} may optionally combine with each other or with any one R² or R¹⁷ to form a ring system, which can be further substituted; wherein R¹⁷ and R¹⁸ represent mono-, di-, tri-, or tetra-substitution, wherein each R¹⁷ or R¹⁸ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹⁷ or any two adjacent R¹⁸ may optionally combine to form a ring, which can be further substituted; wherein R¹⁹ represents mono-, di-, or tri-substitution, wherein each R¹⁹ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹⁹ may optionally combine to form a ring, which can be further substituted; wherein any R³ may optionally combine with any R¹⁹ to form a ring system, which can be further substituted. The other variables have the definitions provided in the above embodiments.

In some other embodiments, the metal complex is a compound selected from the group consisting of:

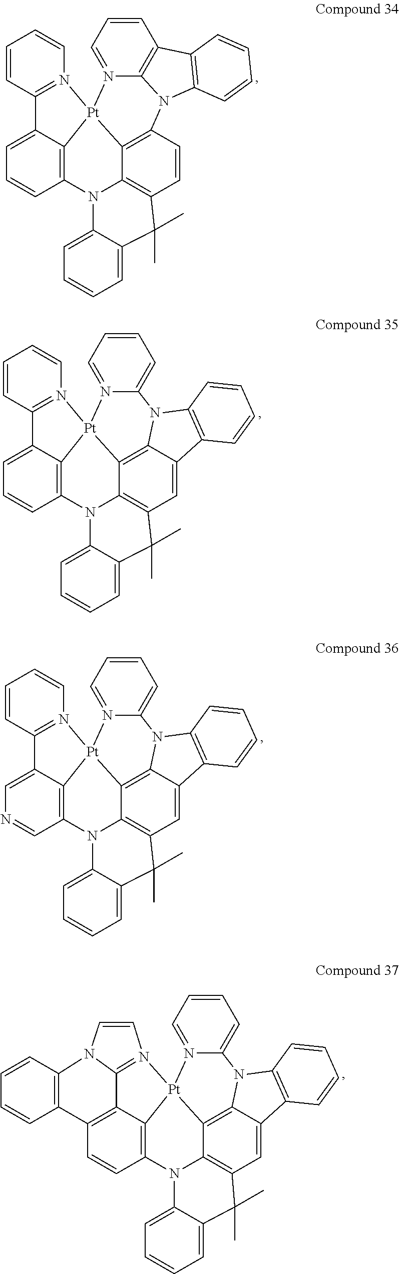

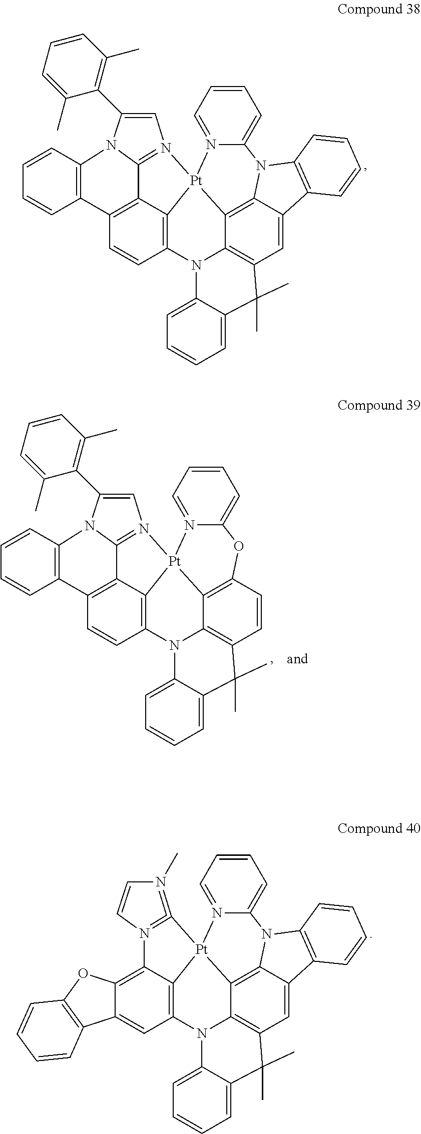

In some embodiments, the metal complex is a compound having Formula (VII):

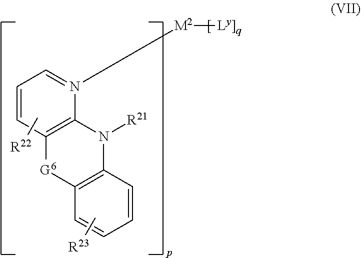

wherein each L_{y} is independently a monodentate ligand, and any two adjacent L^{y} may optionally combine to form a bidentate ligand; wherein M² is cobalt(I), rhodium(I), iridium(I), nickel(II), platinum(II), palladium(II), silver(III), gold(III), or copper(III); wherein p is a value from 1 to the maximum number of ligands that may be attached to M²; wherein p+q is the maximum number of ligands that may be attached to M²; wherein G⁶ is O or CR²⁴R²⁵; wherein R²¹ is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof; wherein R²² represents mono-, di-, or tri-substitution, wherein each R²² is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R² may optionally combine to form a ring, which can be further substituted; wherein R²³ represents mono-, di-, tri-, or tetra-substitution, wherein each R²³ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R³ may optionally combine to form a ring, which can be further substituted; wherein R²⁴ and R²⁵ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R²⁴ and R²⁵ may optionally combine to form a ring, which can be further substituted; wherein R²¹ may optionally combine with any R²³ to form a ring system, which can be further substituted; wherein any of R²⁴ or R²⁵ may optionally combine with any R²² or R²³ to form a ring system, which can be further substituted; andwherein any of R²¹, R²², or R²³ may optionally combine with one or more L_{y} to form a bidentate, tridentate, or tetradentate ligand.

In some embodiments, M² is platinum(II), palladium(II), or gold(III). In some other embodiments, M² is platinum (II).

In some embodiments, G⁶ is O, C(CH₃)₂, or C(C₆H₅)₂.

In some other embodiments, the metal complex is a compound selected from the group consisting of:

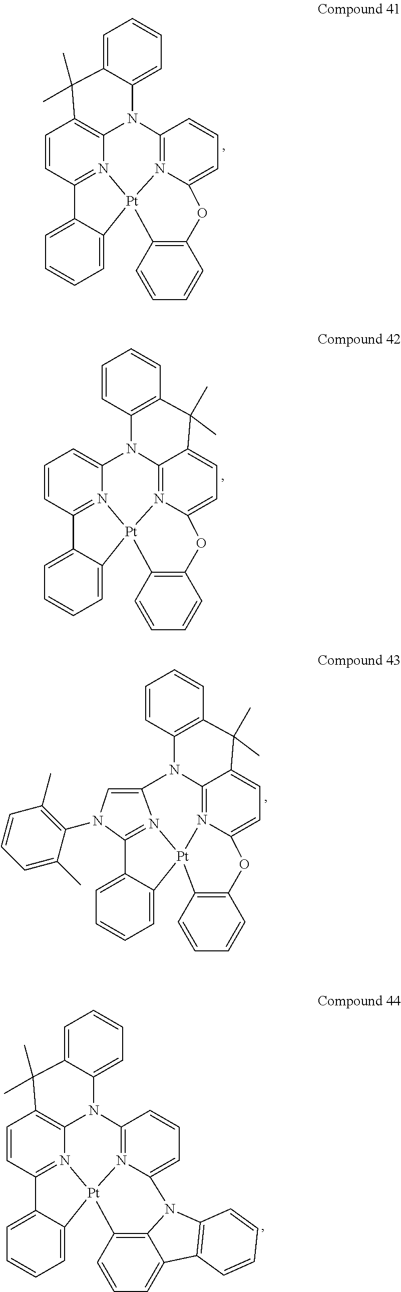

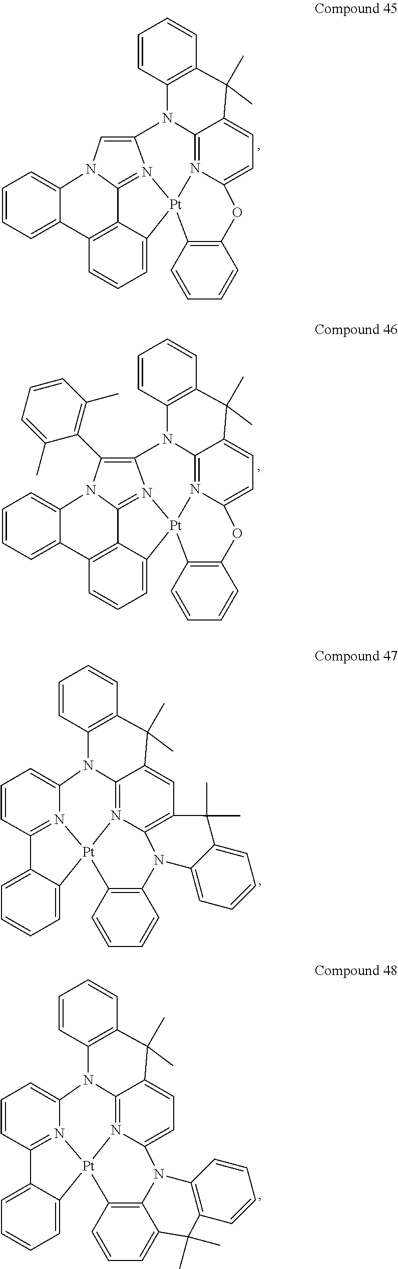

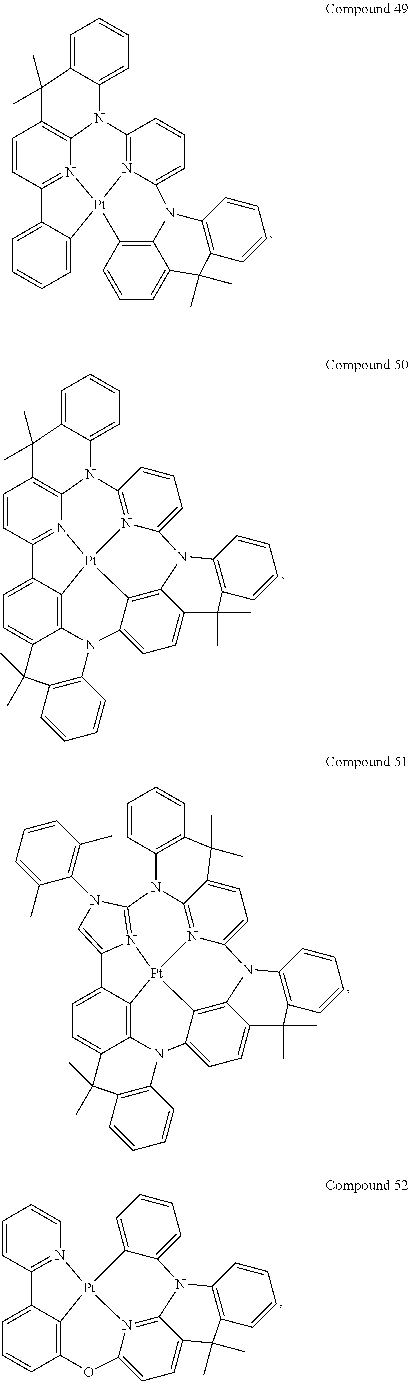

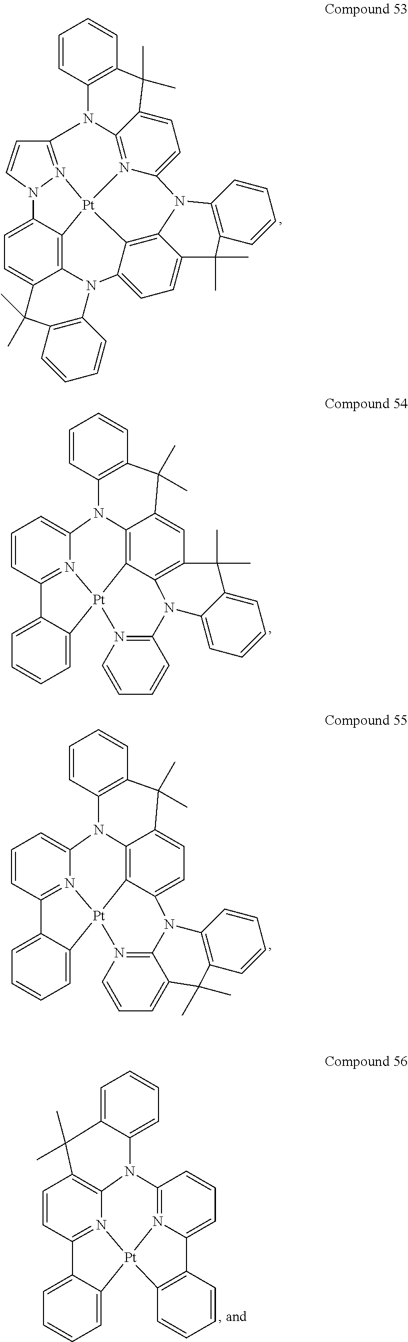

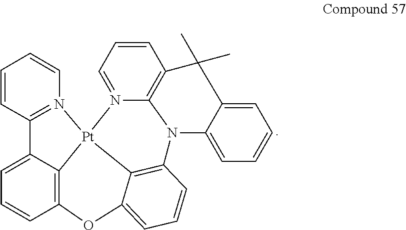

In another aspect, the invention provides devices that include metal complexes having a bridged N,N-diaryl ligand, such as those described in the foregoing paragraphs. In some embodiments, the invention provides a first device comprising a first organic light emitting device, which further comprises: an anode; a cathode; and an organic layer disposed between the anode and the cathode, which comprises a boron-nitrogen heterocycle according to any of the above embodiments. In some embodiments, the first device is a consumer product. In some embodiments, the first device is an organic light emitting device (OLED). In some embodiments, the first device comprises a lighting panel.

In some embodiments, the organic layer of the first device is an emissive layer. In some such embodiments, the emissive layer comprises an emissive dopant. In some embodiments, a metal complex having a bridged N,N-diaryl ligand (as described above) is an emissive dopant. In some other embodiments, a metal complex having a bridged N,N-diaryl ligand (as described above) is a non-emissive dopant.

In some embodiments, the organic layer of the first device comprises a host. In some such embodiments, the host comprises a triphenylene containing benzo-fused thiophene or benzo-fused furan; wherein any substituent in the host is an unfused substituent independently selected from the group consisting of CₙH₂ₙ₊₁, OCₙH₂ₙ₊₁, OAr₁, N(CₙH₂ₙ₊₁)₂, N(Ar₁)(Ar₂), CH═CH—CₙH₂ₙ₊₁, C≡C—CₙH₂ₙ₊₁, Ar₁, Ar₁—Ar₂, and CₙH₂n-Ar₁, or the host has; wherein n is from 1 to 10; and wherein Ar₁ and Ar₂ are independently selected from the group consisting of benzene, biphenyl, naphthalene, triphenylene, carbazole, and heteroaromatic analogs thereof. In some other embodiments, the host comprises a compound selected from the group consisting of: carbazole, dibenzothiophene, dibenzofuran, dibenzoselenophene, azacarbazole, aza-dibenzothiophene, aza-dibenzofuran, and aza-dibenzoselenophene.

In some embodiments, the host is a compound selected from the group consisting of:

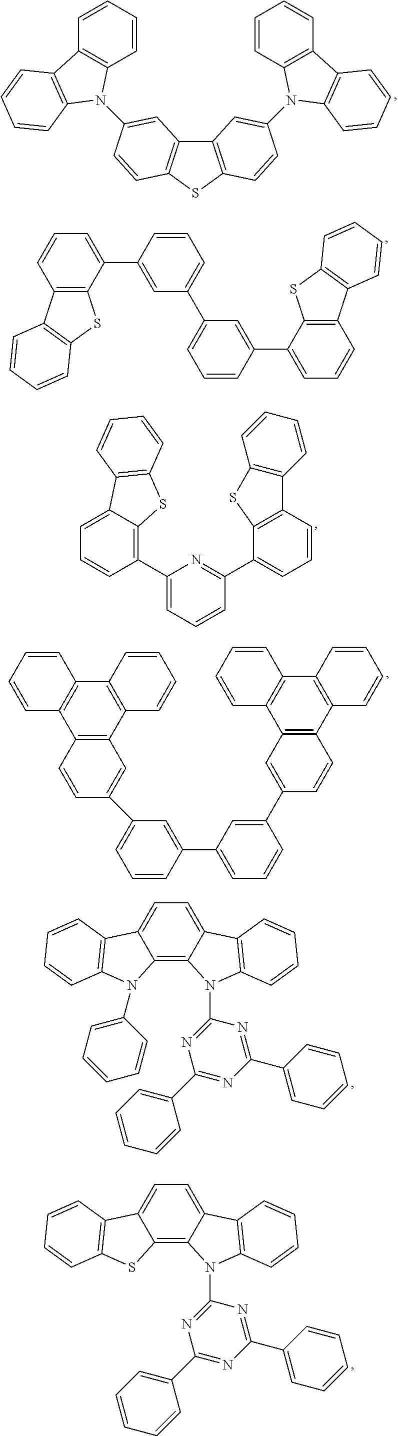

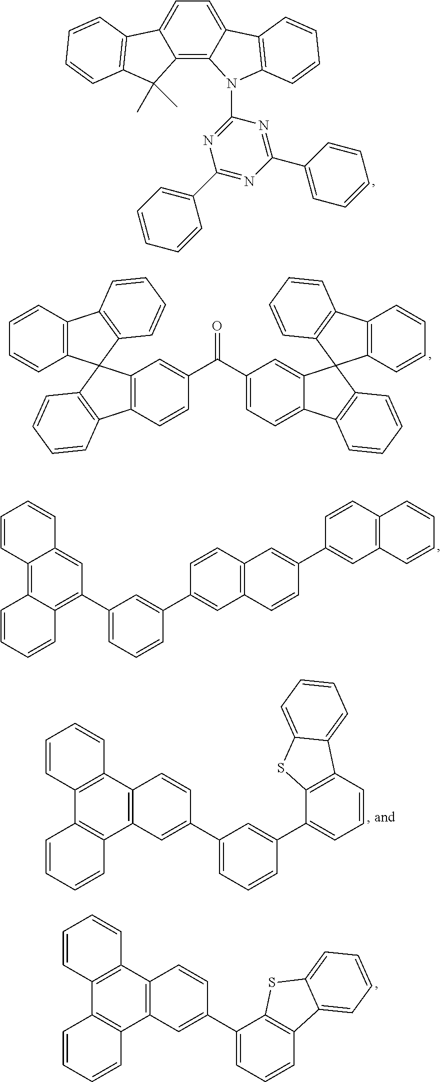

and combinations thereof.

In some embodiments, the host is a metal complex.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### HIL/HTL:

A hole injecting/transporting material to be used in the present invention is not particularly limited, and any compound may be used as long as the compound is typically used as a hole injecting/transporting material. Examples of the material include, but not limit to: a phthalocyanine or porphryin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and sliane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

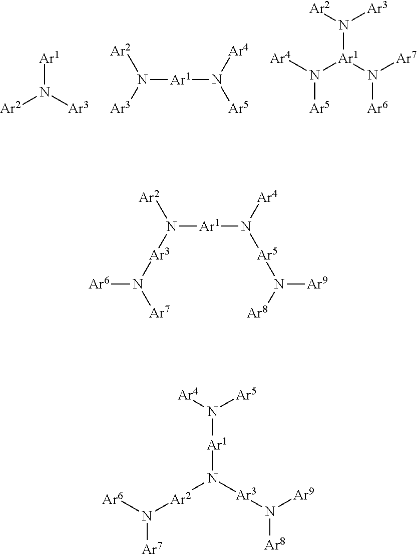

Each of Ar₁ to Ar₉ is selected from the group consisting aromatic hydrocarbon cyclic compounds such as benzene, biphenyl, triphenyl, triphenylene, naphthalene, anthracene, phenalene, phenanthrene, fluorene, pyrene, chrysene, perylene, azulene; group consisting aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and group consisting 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Wherein each Ar is further substituted by a substituent selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof.

In one aspect, Ar₁ to Ar₉ is independently selected from the group consisting of:

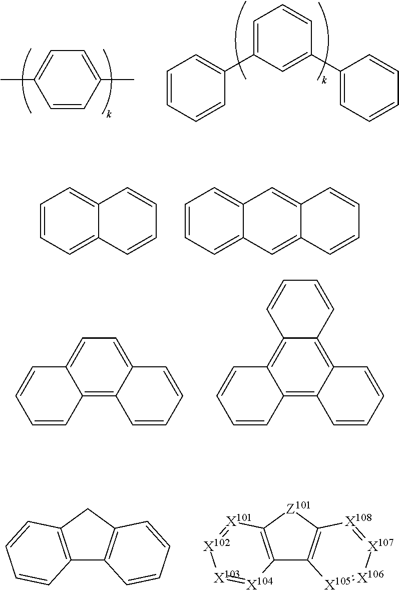

k is an integer from 1 to 20; X¹⁰¹ to X¹⁰⁸ is C (including CH) or N; Z¹⁰¹ is NAr¹, O, or S; Ar¹ has the same group defined above.

Examples of metal complexes used in HIL or HTL include, but not limit to the following general formula:

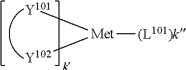

Met is a metal; (Y¹⁰¹-Y¹⁰²) is a bidentate ligand, Y¹⁰¹ and Y¹⁰² are independently selected from C, N, O, P, and S; L¹⁰¹ is another ligand; k′ is an integer value from 1 to the maximum number of ligands that may be attached to the metal; and k′+k″ is the maximum number of ligands that may be attached to the metal.

In one aspect, (Y¹⁰¹-Y¹⁰²) is a 2-phenylpyridine derivative.

In another aspect, (Y¹⁰¹_Y¹⁰²) is a carbene ligand.

In another aspect, Met is selected from Ir, Pt, Os, and Zn.

In a further aspect, the metal complex has a smallest oxidation potential in solution vs. Fc⁺/Fc couple less than about 0.6 V.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. While the Table below categorizes host materials as preferred for devices that emit various colors, any host material may be used with any dopant so long as the triplet criteria is satisfied.

Examples of metal complexes used as host are preferred to have the following general formula:

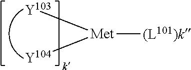

Met is a metal; (Y¹⁰³_Y¹⁰⁴) is a bidentate ligand, Y¹⁰³ and Y¹⁰⁴ are independently selected from C, N, O, P, and S; L¹⁰¹ is another ligand; k′ is an integer value from 1 to the maximum number of ligands that may be attached to the metal; and k′+k″ is the maximum number of ligands that may be attached to the metal.

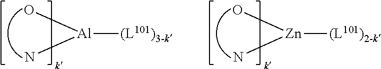

(O—N) is a bidentate ligand, having metal coordinated to atoms O and N.

In another aspect, Met is selected from Ir and Pt.

In a further aspect, (Y¹⁰³_Y¹⁰⁴) is a carbene ligand.

Examples of organic compounds used as host are selected from the group consisting aromatic hydrocarbon cyclic compounds such as benzene, biphenyl, triphenyl, triphenylene, naphthalene, anthracene, phenalene, phenanthrene, fluorene, pyrene, chrysene, perylene, azulene; group consisting aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and group consisting 2 to 10 cyclic structural units which are groups of the same type or different types selected from the aromatic hydrocarbon cyclic group and the aromatic heterocyclic group and are bonded to each other directly or via at least one of oxygen atom, nitrogen atome, sulfur atom, silicon atom, phosphorus atom, boron atom, chain structural unit and the aliphatic cyclic group. Wherein each group is further substituted by a substituent selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof.

In one aspect, host compound contains at least one of the following groups in the molecule:

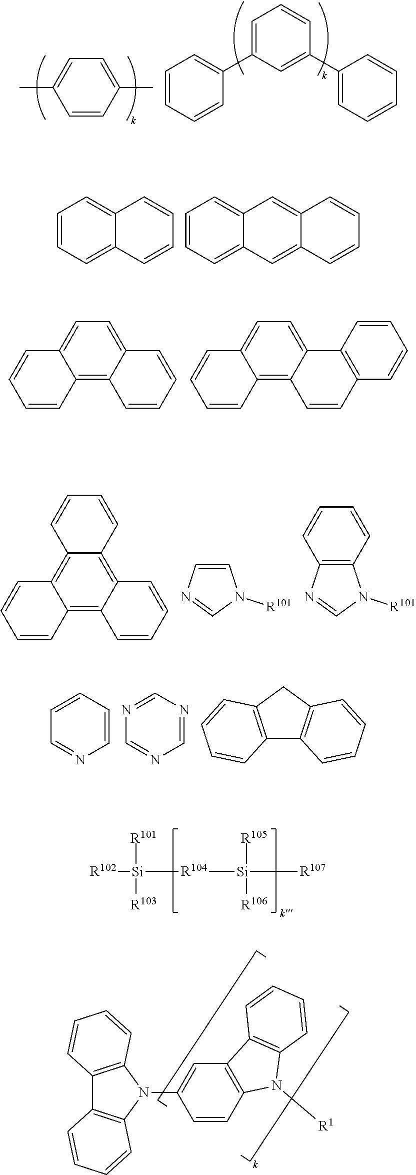

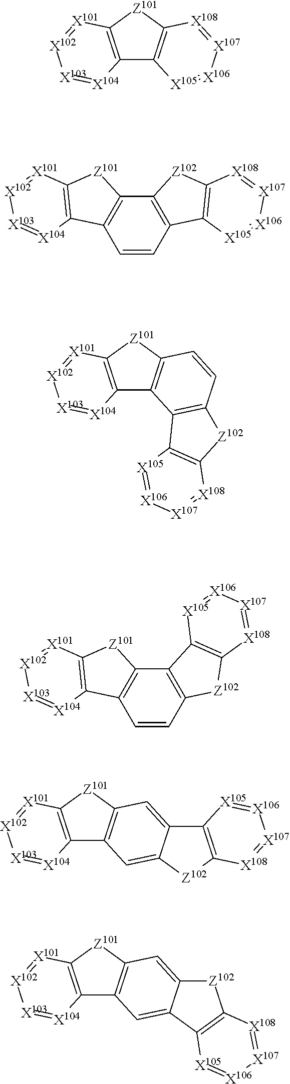

R¹⁰¹ to R¹⁰⁷ is independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, when it is aryl or heteroaryl, it has the similar definition as Ar's mentioned above.

k is an integer from 1 to 20; k′″ is an integer from 0 to 20.

X¹⁰¹ to X¹⁰⁸ is selected from C (including CH) or N. Z¹⁰¹ and Z¹⁰² is selected from NR¹⁰¹, O, or S.

### HBL:

A hole blocking layer (HBL) may be used to reduce the number of holes and/or excitons that leave the emissive layer. The presence of such a blocking layer in a device may result in substantially higher efficiencies as compared to a similar device lacking a blocking layer. Also, a blocking layer may be used to confine emission to a desired region of an OLED.

In one aspect, compound used in HBL contains the same molecule or the same functional groups used as host described above.

In another aspect, compound used in HBL contains at least one of the following groups in the molecule:

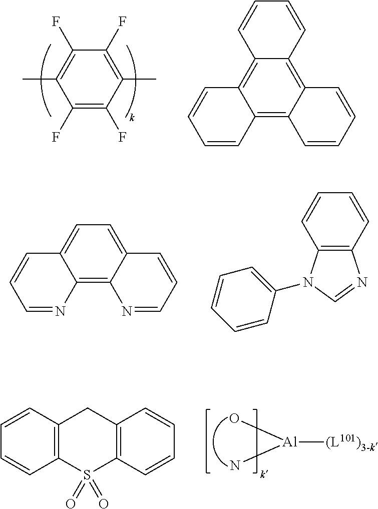

k is an integer from 1 to 20; L¹⁰¹ is another ligand, k′ is an integer from 1 to 3.

### ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

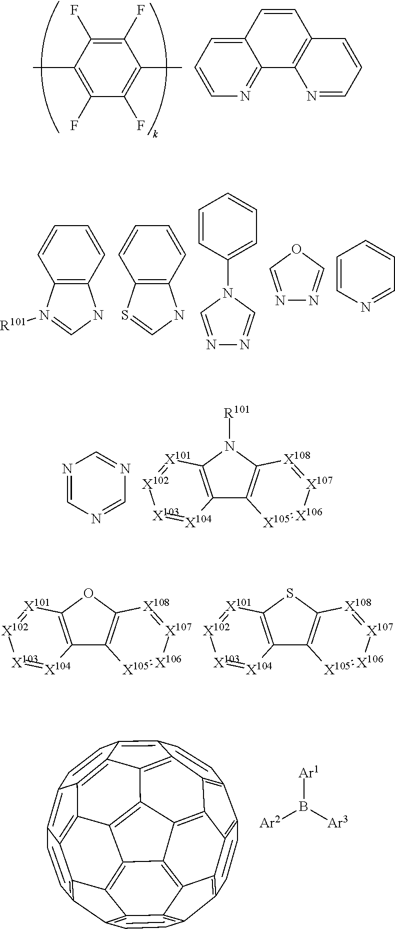

R¹⁰¹ is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, when it is aryl or heteroaryl, it has the similar definition as Ar's mentioned above.

Ar¹ to Ar³ has the similar definition as Ar's mentioned above.

k is an integer from 1 to 20.

X¹⁰¹ to X¹⁰⁸ is selected from C (including CH) or N.

In another aspect, the metal complexes used in ETL contains, but not limit to the following general formula:

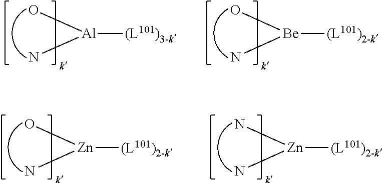

(O—N) or (N—N) is a bidentate ligand, having metal coordinated to atoms O, Nor N, N; L¹⁰¹ is another ligand; k′ is an integer value from 1 to the maximum number of ligands that may be attached to the metal.

In any above-mentioned compounds used in each layer of the OLED device, the hydrogen atoms can be partially or fully deuterated. Thus, any specifically listed substituent, such as, without limitation, methyl, phenyl, pyridyl, etc. encompasses undeuterated, partially deuterated, and fully deuterated versions thereof. Similarly, classes of substituents such as, without limitation, alkyl, aryl, cycloalkyl, heteroaryl, etc. also encompass undeuterated, partially deuterated, and fully deuterated versions thereof.

In addition to and/or in combination with the materials disclosed herein, many hole injection materials, hole transporting materials, host materials, dopant materials, exiton/hole blocking layer materials, electron transporting and electron injecting materials may be used in an OLED. Non-limiting examples of the materials that may be used in an OLED in combination with materials disclosed herein are listed in Table 1 below. Table 1 lists non-limiting classes of materials, non-limiting examples of compounds for each class, and references that disclose the materials.

TABLE 1

| | | |
|---|---|---|
| MATERIAL | EXAMPLES OF MATERIAL | PUBLICATIONS |

Hole injection materials

| | | |
|---|---|---|
| Phthalocyanine and porphryin compounds | 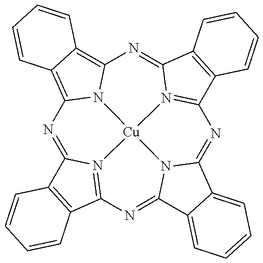 | Appl. Phys. Lett. 69, 2160 (1996) |
| Starburst triarylamines | 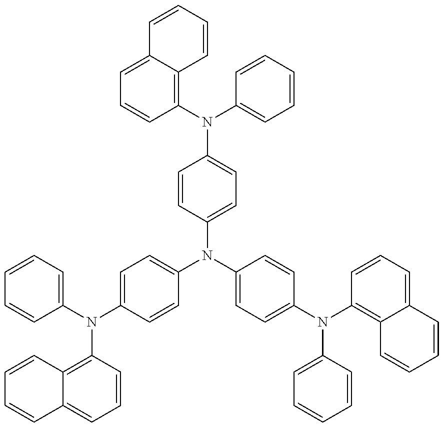 [SMILES: c1ccc(N(c2ccc(N(c3ccc(N(c4ccccc4)c4cccc5ccccc45)cc3)c3ccc(N(c4ccccc4)c4cccc5ccccc45)cc3)cc2)c2cccc3ccccc23)cc1] | J. Lumin. 72-74, 985 (1997) |
| CFₓ Fluorohydrocarbon polymer | 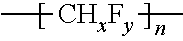 | Appl. Phys. Lett. 78, 673 (2001) |
| Conducting polymers (e.g., PEDOT:PSS, polyaniline, polypthiophene) | 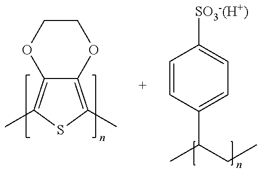 | Synth. Met. 87, 171 (19997) WO2007002683 |
| Phosphonic acid and sliane SAMs | 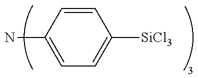 | US20030162053 |
| Triarylamine or polythiophene polymers with conductivity dopants | 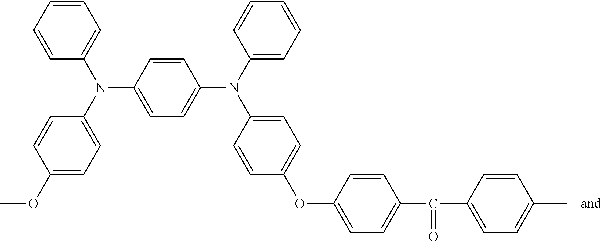 | EP1725079A1 |
| | 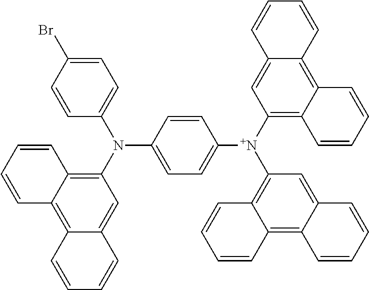 [SMILES: Brc1ccc(N(c2ccc([NH+](c3cc4ccccc4c4ccccc34)c3cc4ccccc4c4ccccc34)cc2)c2cc3ccccc3c3ccccc23)cc1] | |
| | 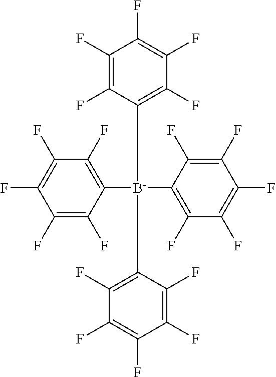 [SMILES: Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F] | |
| Organic compounds with conductive inorganic compounds, such as molybdenum and tungsten oxides | 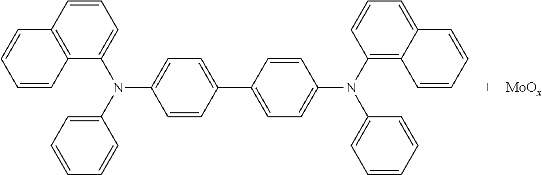 [SMILES: c1ccc(N(c2ccc(-c3ccc(N(c4ccccc4)c4cccc5ccccc45)cc3)cc2)c2cccc3ccccc23)cc1] | US20050123751 SID Symposium Digest, 37, 923 (2006) WO2009018009 |
| n-type semiconducting organic complexes | 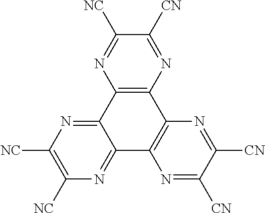 [SMILES: N#Cc1nc2c3nc(C#N)c(C#N)nc3c3nc(C#N)c(C#N)nc3c2nc1C#N] | US20020158242 |
| Metal organometallic complexes | 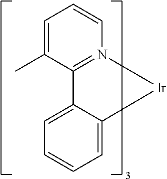 | US20060240279 |
| Cross-linkable compounds | 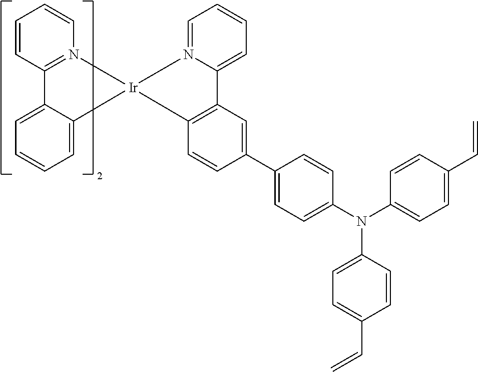 | US20080220265 |
| Polythiophene based polymers and copolymers | 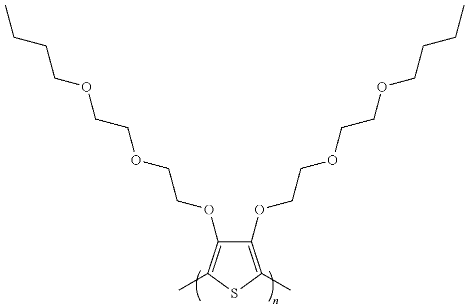 | WO 2011075644 EP2350216 |

Hole transporting materials

| | | |
|---|---|---|
| Triarylamines (e.g., TPD, ▭-NPD) | 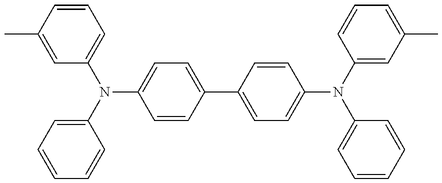 | Appl. Phys. Lett. 51, 913 (1987) |
| | 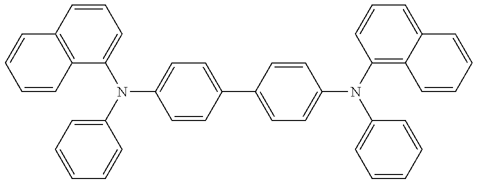 [SMILES: c1ccc(N(c2ccc(-c3ccc(N(c4ccccc4)c4cccc5ccccc45)cc3)cc2)c2cccc3ccccc23)cc1] | U.S. Pat. No. 5,061,569 |
| | 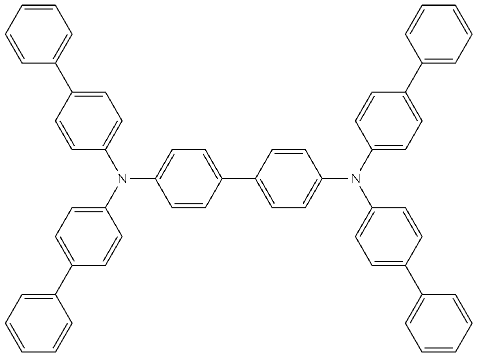 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1] | EP650955 |
| | 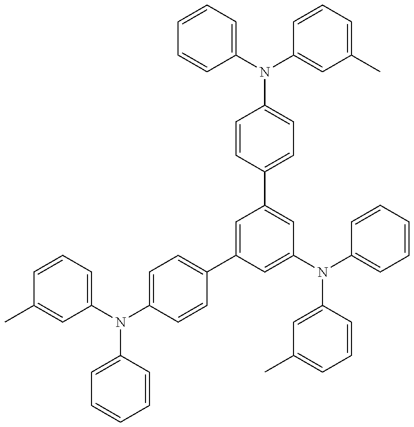 [SMILES: Cc1cccc(N(c2ccccc2)c2ccc(-c3cc(-c4ccc(N(c5ccccc5)c5cccc(C)c5)cc4)cc(N(c4ccccc4)c4cccc(C)c4)c3)cc2)c1] | J. Mater. Chem. 3, 319 (1993) |
| | 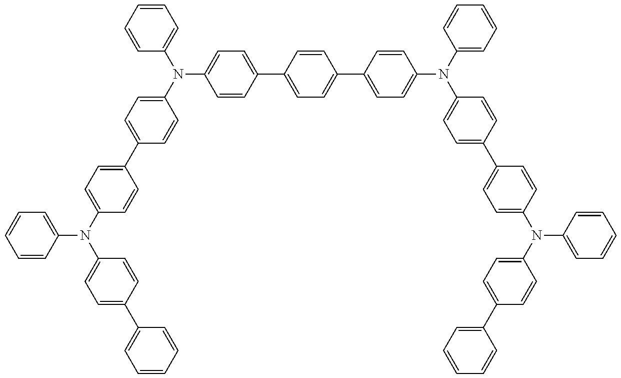 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1] | Appl. Phys. Lett. 90, 183503 (2007) |
| | 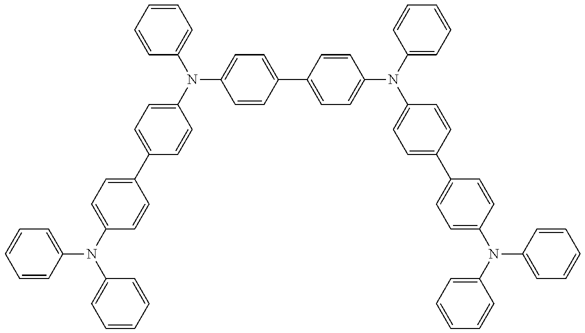 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1] | Appl. Phys. Lett. 90, 183503 (2007) |
| Triaylamine on spirofluorene core | 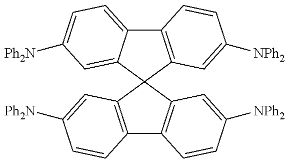 | Synth. Met. 91, 209 (1997) |
| Arylamine carbazole compounds | 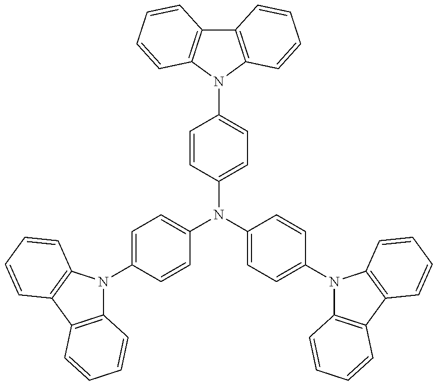 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1] | Adv. Mater. 6, 677 (1994), US20080124572 |
| Triarylamine with (di)benzothiophene/(di) benzofuran | 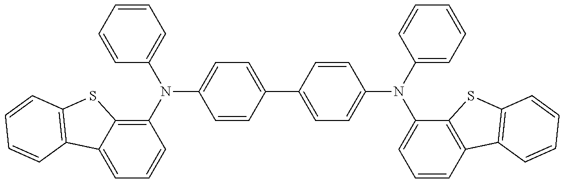 [SMILES: c1ccc(N(c2ccc(-c3ccc(N(c4ccccc4)c4cccc5c4sc4ccccc45)cc3)cc2)c2cccc3c2sc2ccccc23)cc1] | US20070278938, US20080106190 US20110163302 |
| Indolocarbazoles | 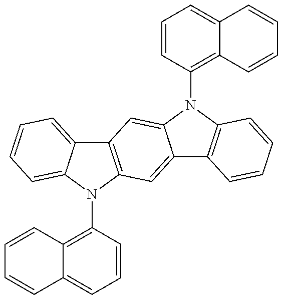 [SMILES: c1ccc2c(-n3c4ccccc4c4cc5c(cc43)c3ccccc3n5-c3cccc4ccccc34)cccc2c1] | Synth. Met. 111, 421 (2000) |
| Isoindole compounds | 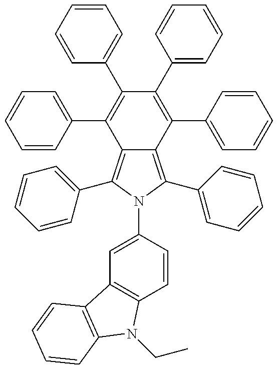 [SMILES: CCn1c2ccccc2c2cc(-n3c(-c4ccccc4)c4c(-c5ccccc5)c(-c5ccccc5)c(-c5ccccc5)c(-c5ccccc5)c4c3-c3ccccc3)ccc21] | Chem. Mater. 15, 3148 (2003) |
| Metal carbene complexes | 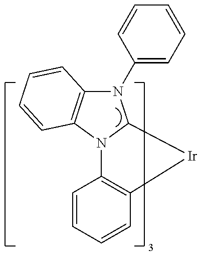 | US20080018221 |

Phosphorescent OLED host materials
Red hosts

| | | |
|---|---|---|
| Arylcarbazoles | 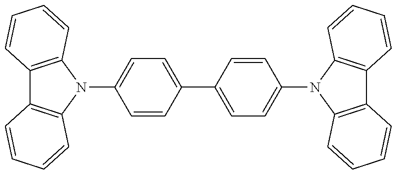 [SMILES: c1ccc2c(c1)c1ccccc1n2-c1ccc(-c2ccc(-n3c4ccccc4c4ccccc43)cc2)cc1] | Appl. Phys. Lett. 78, 1622 (2001) |
| Metal 8-hydroxyquinolates (e.g., Alq₃, BAlq) | 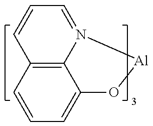 | Nature 395, 151 (1998) |
| | 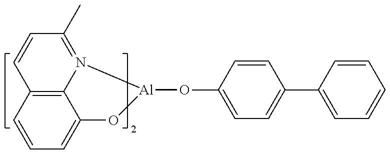 | US20060202194 |
| | 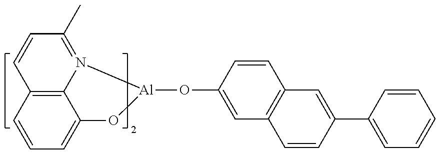 | WO2005014551 |
| | 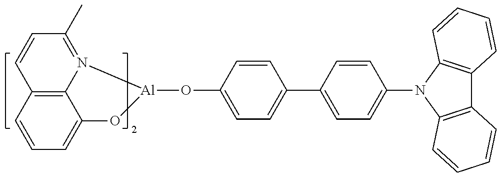 | WO2006072002 |
| Metal phenoxybenzothiazole compounds | 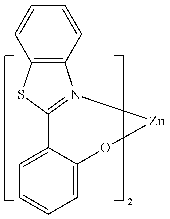 | Appl. Phys. Lett. 90, 123509 (2007) |
| Conjugated oligomers and polymers (e.g., polyfluorene) | 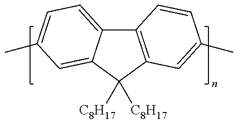 | Org. Electron. 1, 15 (2000) |
| Aromatic fused rings | 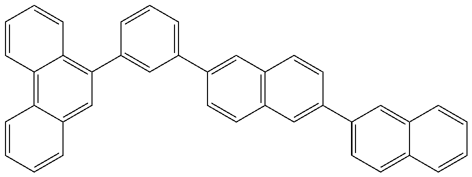 [SMILES: c1cc(-c2ccc3cc(-c4ccc5ccccc5c4)ccc3c2)cc(-c2cc3ccccc3c3ccccc23)c1] | WO2009066779, WO2009066778, WO2009063833, US20090045731, US20090045730, WO2009008311, US20090008605, US20090009065 |
| Zinc complexes | 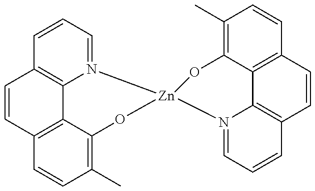 | WO2010056066 |
| Chrysene based compounds | 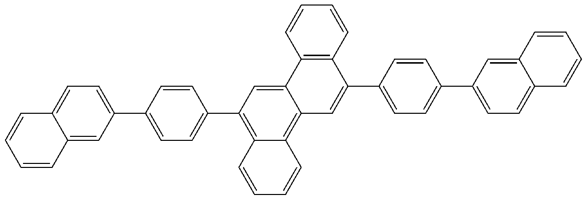 [SMILES: c1ccc2cc(-c3ccc(-c4cc5c6ccccc6c(-c6ccc(-c7ccc8ccccc8c7)cc6)cc5c5ccccc45)cc3)ccc2c1] | WO2011086863 |

Green hosts

| | | |
|---|---|---|
| Arylcarbazoles | 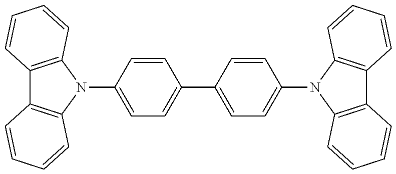 [SMILES: c1ccc2c(c1)c1ccccc1n2-c1ccc(-c2ccc(-n3c4ccccc4c4ccccc43)cc2)cc1] | Appl. Phys. Lett. 78, 1622 (2001) |
| | 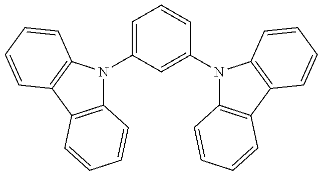 [SMILES: c1cc(-n2c3ccccc3c3ccccc32)cc(-n2c3ccccc3c3ccccc32)c1] | US20030175553 |
| | 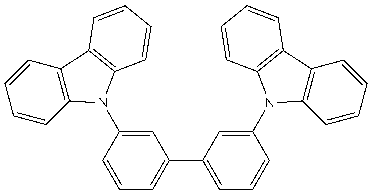 [SMILES: c1cc(-c2cccc(-n3c4ccccc4c4ccccc43)c2)cc(-n2c3ccccc3c3ccccc32)c1] | WO2001039234 |
| Aryltriphenylene compounds | 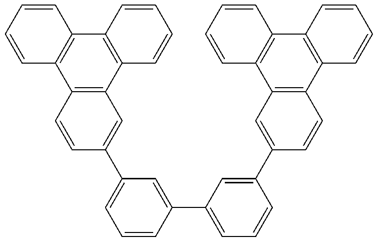 [SMILES: c1cc(-c2cccc(-c3ccc4c5ccccc5c5ccccc5c4c3)c2)cc(-c2ccc3c4ccccc4c4ccccc4c3c2)c1] | US20060280965 |
| | 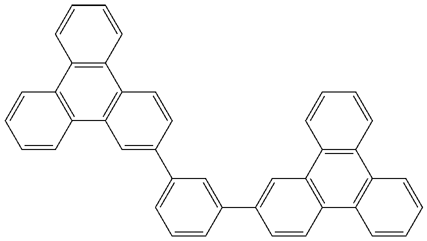 [SMILES: c1cc(-c2ccc3c4ccccc4c4ccccc4c3c2)cc(-c2ccc3c4ccccc4c4ccccc4c3c2)c1] | US20060280965 |
| | 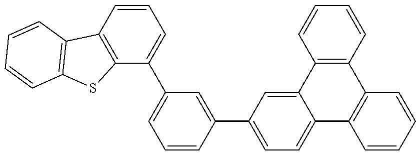 [SMILES: c1cc(-c2ccc3c4ccccc4c4ccccc4c3c2)cc(-c2cccc3c2sc2ccccc23)c1] | WO2009021126 |
| Poly-fused heteroaryl compounds | 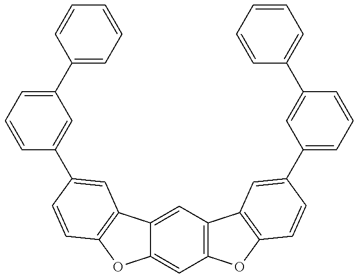 [SMILES: c1ccc(-c2cccc(-c3ccc4oc5cc6oc7ccc(-c8cccc(-c9ccccc9)c8)cc7c6cc5c4c3)c2)cc1] | US20090309488 US20090302743 US20100012931 |
| Donor acceptor type molecules | 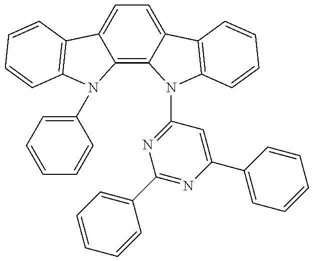 [SMILES: c1ccc(-c2cc(-n3c4ccccc4c4ccc5c6ccccc6n(-c6ccccc6)c5c43)nc(-c3ccccc3)n2)cc1] | WO2008056746 |
| | 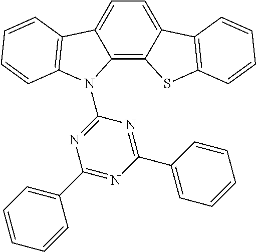 [SMILES: c1ccc(-c2nc(-c3ccccc3)nc(-n3c4ccccc4c4ccc5c6ccccc6sc5c43)n2)cc1] | WO2010107244 |
| Aza-carbazole/DBT/ DBF | 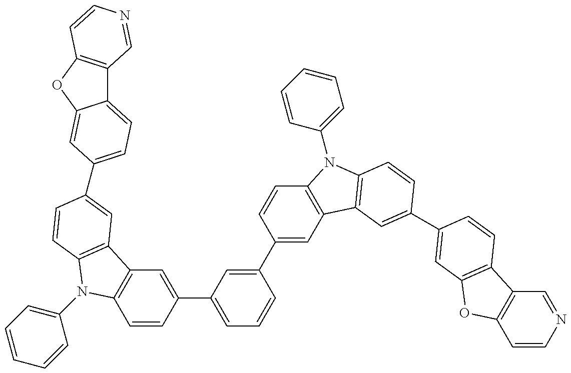 [SMILES: c1ccc(-n2c3ccc(-c4cccc(-c5ccc6c(c5)c5cc(-c7ccc8c(c7)oc7ccncc78)ccc5n6-c5ccccc5)c4)cc3c3cc(-c4ccc5c(c4)oc4ccncc45)ccc32)cc1] | JP2008074939 |
| | 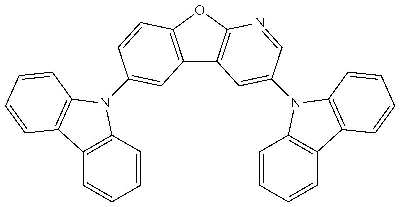 [SMILES: c1ccc2c(c1)c1ccccc1n2-c1ccc2oc3ncc(-n4c5ccccc5c5ccccc54)cc3c2c1] | US20100187984 |
| Polymers (e.g., PVK) | 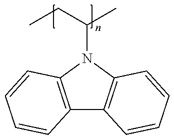 | Appl. Phys. Lett. 77, 2280 (2000) |
| Spirofluorene compounds | 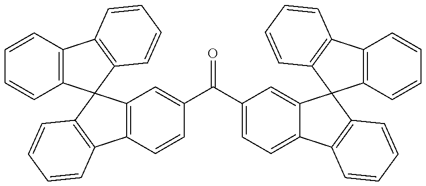 [SMILES: O=C(c1ccc2c(c1)C1(c3ccccc3-c3ccccc31)c1ccccc1-2)c1ccc2c(c1)C1(c3ccccc3-c3ccccc31)c1ccccc1-2] | WO2004093207 |
| Metal phenoxybenzooxazole compounds | 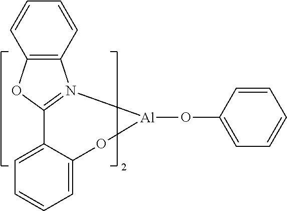 | WO2005089025 |
| | 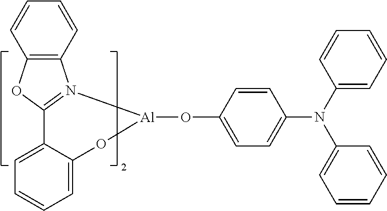 | WO2006132173 |
| | 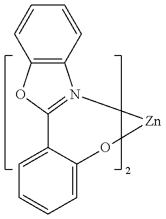 | JP200511610 |
| Spirofluorene- carbazole compounds | 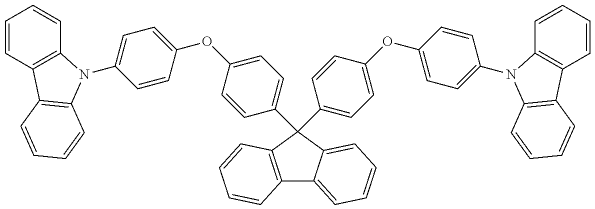 [SMILES: c1ccc2c(c1)-c1ccccc1C2(c1ccc(Oc2ccc(-n3c4ccccc4c4ccccc43)cc2)cc1)c1ccc(Oc2ccc(-n3c4ccccc4c4ccccc43)cc2)cc1] | JP2007254297 |
| | 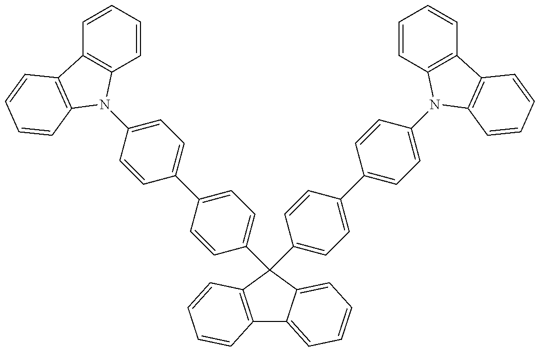 [SMILES: c1ccc2c(c1)-c1ccccc1C2(c1ccc(-c2ccc(-n3c4ccccc4c4ccccc43)cc2)cc1)c1ccc(-c2ccc(-n3c4ccccc4c4ccccc43)cc2)cc1] | JP2007254297 |
| Indolocabazoles | 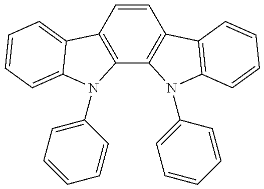 [SMILES: c1ccc(-n2c3ccccc3c3ccc4c5ccccc5n(-c5ccccc5)c4c32)cc1] | WO2007063796 |
| | 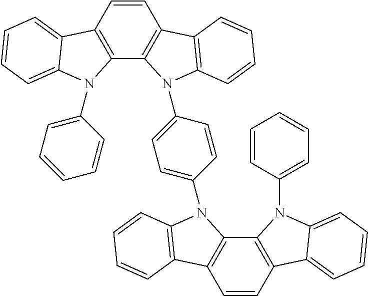 [SMILES: c1ccc(-n2c3ccccc3c3ccc4c5ccccc5n(-c5ccc(-n6c7ccccc7c7ccc8c9ccccc9n(-c9ccccc9)c8c76)cc5)c4c32)cc1] | WO2007063754 |
| 5-member ring electron deficient heterocycles (e.g., triazole, oxadiazole) | 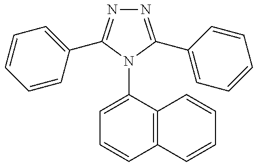 [SMILES: c1ccc(-c2nnc(-c3ccccc3)n2-c2cccc3ccccc23)cc1] | J. Appl. Phys. 90, 5048 (2001) |
| | 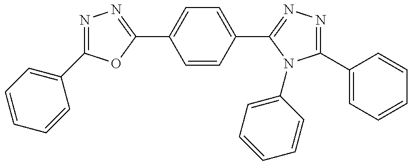 [SMILES: c1ccc(-c2nnc(-c3ccc(-c4nnc(-c5ccccc5)n4-c4ccccc4)cc3)o2)cc1] | WO2004107822 |
| Tetraphenylene complexes | 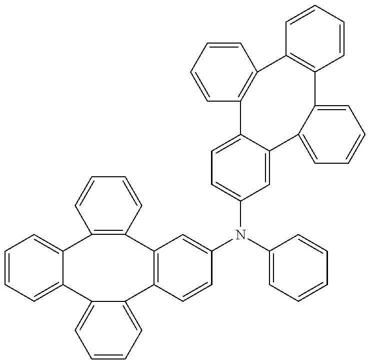 [SMILES: c1ccc(N(c2ccc3c(c2)-c2ccccc2-c2ccccc2-c2ccccc2-3)c2ccc3c(c2)-c2ccccc2-c2ccccc2-c2ccccc2-3)cc1] | US20050112407 |
| Metal phenoxypyridine compounds | 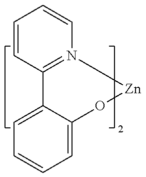 | WO2005030900 |
| Metal coordination complexes (e.g., Zn, Al with N\hat{ }N ligands) | 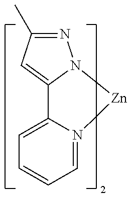 | US20040137268, US20040137267 |

Blue hosts

| | | |
|---|---|---|
| Arylcarbazoles | 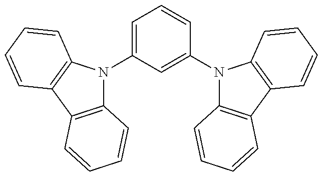 [SMILES: c1cc(-n2c3ccccc3c3ccccc32)cc(-n2c3ccccc3c3ccccc32)c1] | Appl. Phys. Lett, 82, 2422 (2003) |
| | 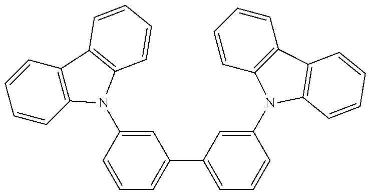 [SMILES: c1cc(-c2cccc(-n3c4ccccc4c4ccccc43)c2)cc(-n2c3ccccc3c3ccccc32)c1] | US20070190359 |
| Dibenzothiophene/ Dibenzofuran- carbazole compounds | 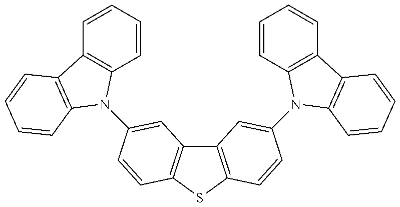 [SMILES: c1ccc2c(c1)c1ccccc1n2-c1ccc2sc3ccc(-n4c5ccccc5c5ccccc54)cc3c2c1] | WO2006114966, US20090167162 |
| | 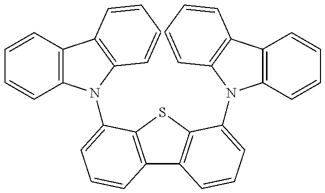 [SMILES: c1cc(-n2c3ccccc3c3ccccc32)c2sc3c(-n4c5ccccc5c5ccccc54)cccc3c2c1] | US20090167162 |
| | 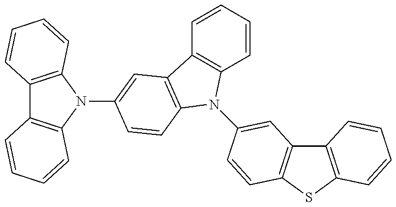 [SMILES: c1ccc2c(c1)sc1ccc(-n3c4ccccc4c4cc(-n5c6ccccc6c6ccccc65)ccc43)cc12] | WO2009086028 |
| | 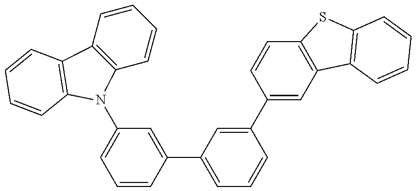 [SMILES: c1cc(-c2cccc(-n3c4ccccc4c4ccccc43)c2)cc(-c2ccc3sc4ccccc4c3c2)c1] | US20090030202, US20090017330 |
| | 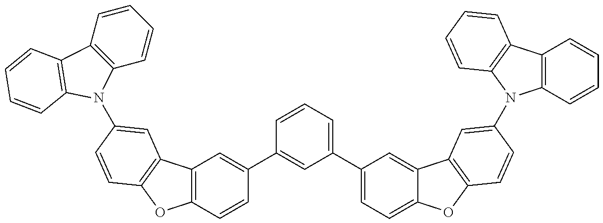 [SMILES: c1cc(-c2ccc3oc4ccc(-n5c6ccccc6c6ccccc65)cc4c3c2)cc(-c2ccc3oc4ccc(-n5c6ccccc6c6ccccc65)cc4c3c2)c1] | US20100084966 |
| Silicon aryl compounds | 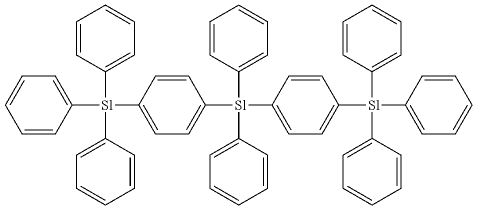 | US20050238919 |
| | 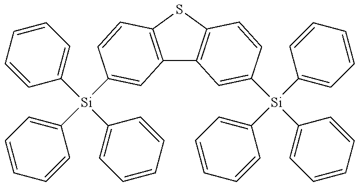 [SMILES: c1ccc([Si](c2ccccc2)(c2ccccc2)c2ccc3sc4ccc([Si](c5ccccc5)(c5ccccc5)c5ccccc5)cc4c3c2)cc1] | WO2009003898 |
| Silicon/Germanium aryl compounds | 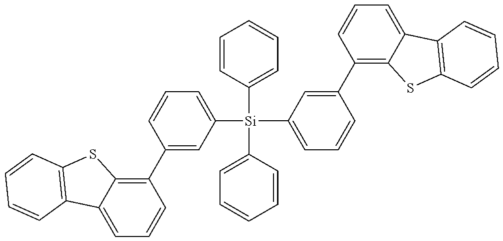 [SMILES: c1ccc([Si](c2ccccc2)(c2cccc(-c3cccc4c3sc3ccccc34)c2)c2cccc(-c3cccc4c3sc3ccccc34)c2)cc1] | EP2034538A |
| Aryl benzoyl ester | 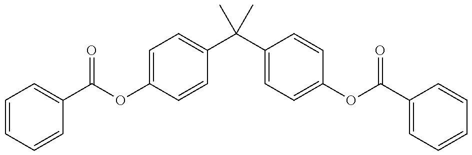 [SMILES: CC(C)(c1ccc(OC(=O)c2ccccc2)cc1)c1ccc(OC(=O)c2ccccc2)cc1] | WO2006100298 |
| Carbazole linked by non-conjugated groups | 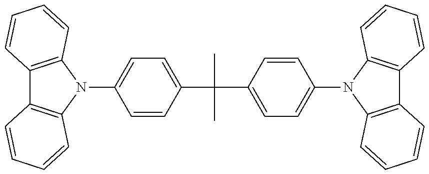 [SMILES: CC(C)(c1ccc(-n2c3ccccc3c3ccccc32)cc1)c1ccc(-n2c3ccccc3c3ccccc32)cc1] | US20040115476 |
| Aza-carbazoles | 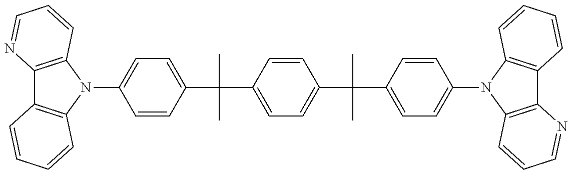 [SMILES: CC(C)(c1ccc(-n2c3ccccc3c3ncccc32)cc1)c1ccc(C(C)(C)c2ccc(-n3c4ccccc4c4ncccc43)cc2)cc1] | US20060121308 |
| High triplet metal organometallic complex | 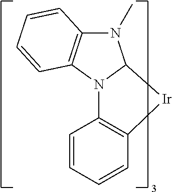 | U.S. Pat. No. 7,154,114 |

Phosphorescent dopants
Red dopants

| | | |
|---|---|---|
| Heavy metal porphyrins (e.g., PtOEP) | 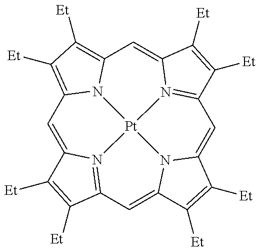 | Nature 395, 151 (1998) |
| Iridium(III) organometallic complexes | 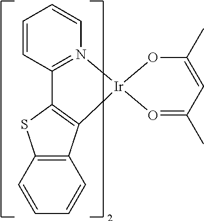 | Appl. Phys. Lett. 78, 1622 (2001) |
| | 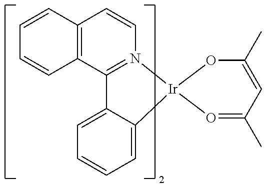 | US2006835469 |
| | 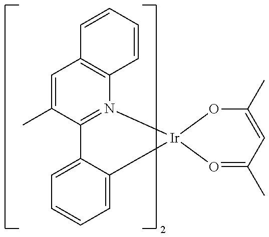 | US2006835469 |
| | 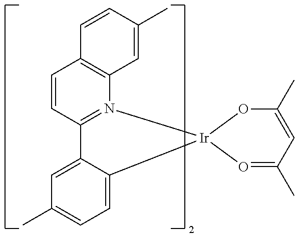 | US20060202194 |
| | 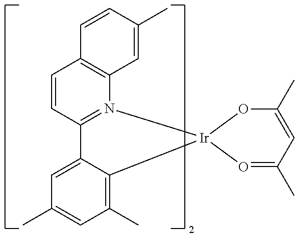 | US20060202194 |
| | 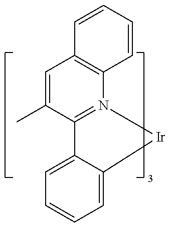 | US20070087321 |
| | 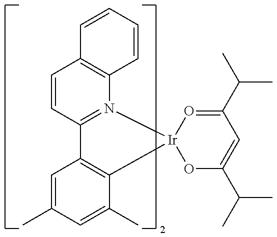 | US20080261076 US20100090591 |
| | 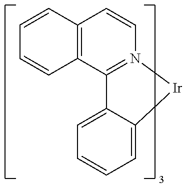 | US20070087321 |
| | 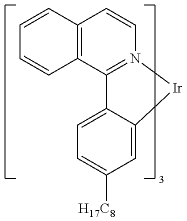 | Adv. Mater. 19, 739 (2007) |
| | 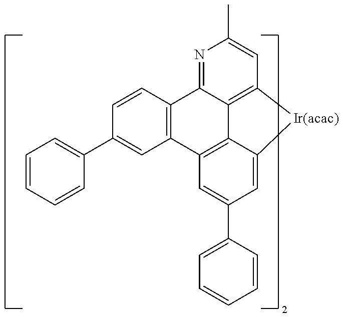 | WO2009100991 |
| | 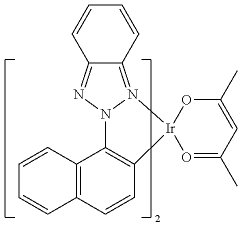 | WO2008101842 |
| | 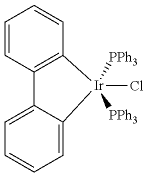 | U.S. Pat. No. 7,232,618 |
| Platinum(II) organometallic complexes | 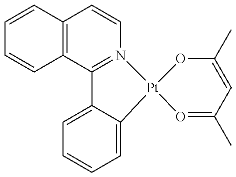 | WO2003040257 |
| | 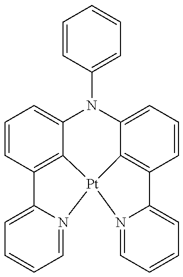 | US20070103060 |
| Osminum(III) complexes | 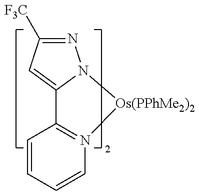 | Chem. Mater. 17, 3532 (2005) |
| Ruthenium(II) complexes | 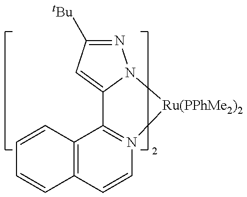 | Adv. Mater. 17, 1059 (2005) |
| Rhenium (I), (II), and (III) complexes | 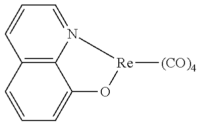 | US20050244673 |

Green dopants

| | | |
|---|---|---|
| Iridium(III) organometallic complexes | 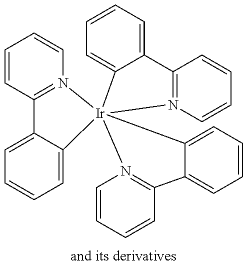 | Inorg. Chem. 40, 1704 (2001) |
| | 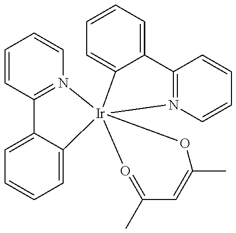 | US20020034656 |
| | 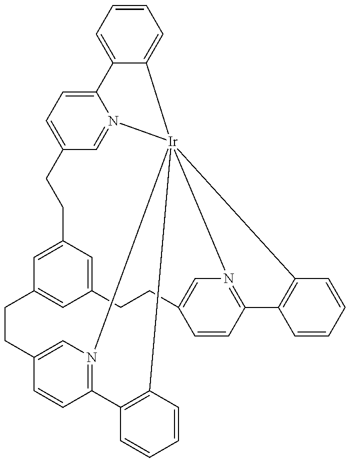 | U.S. Pat. No. 7,332,232 |
| | 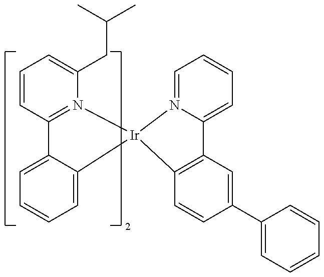 | US20090108737 |
| | 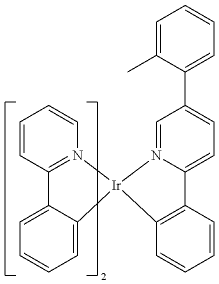 | WO2010028151 |
| | 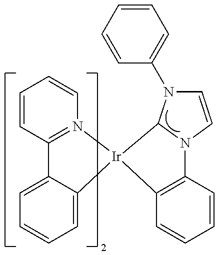 | EP1841834B |
| | 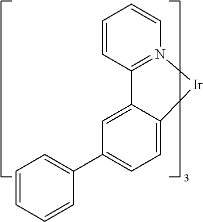 | US20060127696 |
| | 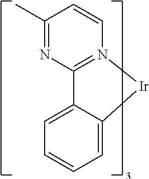 | US20090039776 |
| | 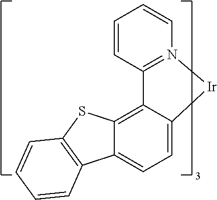 | U.S. Pat. No. 6,921,915 |
| | 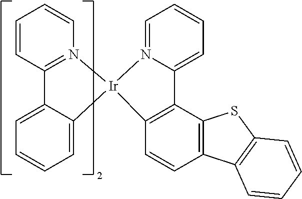 | US20100244004 |
| | 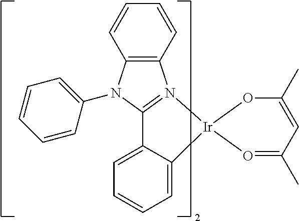 | U.S. Pat. No. 6,687,266 |
| | 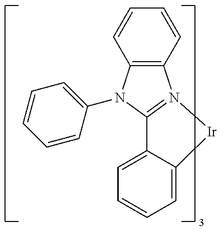 | Chem. Mater. 16, 2480 (2004) |
| | 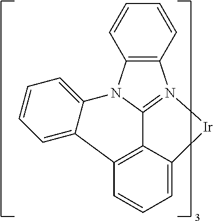 | US20070190359 |
| | 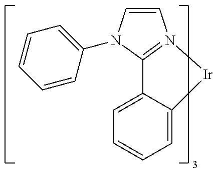 | US 20060008670 JP2007123392 |
| | 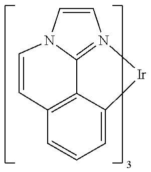 | WO2010086089, WO2011044988 |
| | 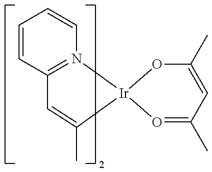 | Adv. Mater. 16, 2003 (2004) |
| | 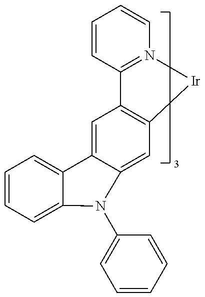 | Angew. Chem. Int. Ed. 2006, 45, 7800 |
| | 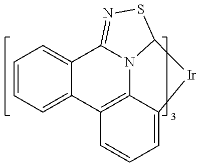 | WO2009050290 |
| | 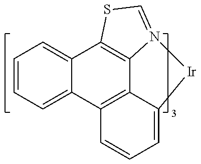 | US20090165846 |
| | 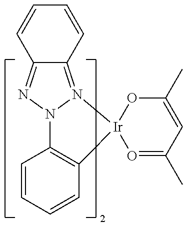 | US20080015355 |
| | 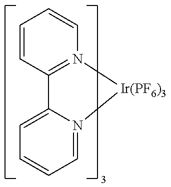 | US20010015432 |
| | 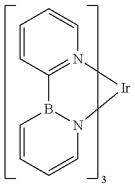 | US20100295032 |
| Monomer for polymeric metal organometallic compounds | 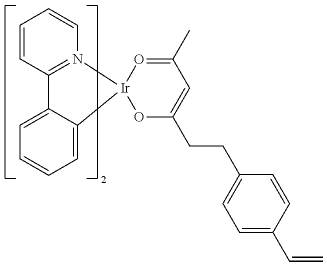 | U.S. Pat. No. 7,250,226, U.S. Pat. No. 7,396,598 |
| Pt(II) organometallic complexes, including polydentated ligands | 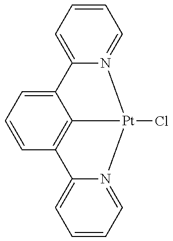 | Appl. Phys. Lett. 86, 153505 (2005) |
| | 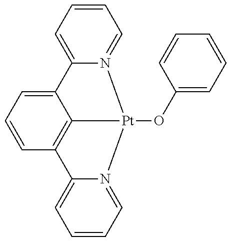 | Appl. Phys. Lett. 86, 153505 (2005) |
| | 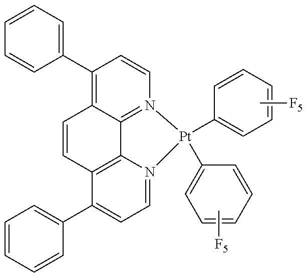 | Chem. Lett. 34, 592 (2005) |
| | 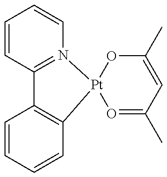 | WO2002015645 |
| | 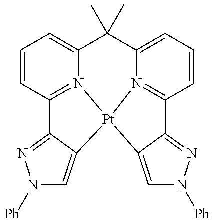 | US20060263635 |
| | 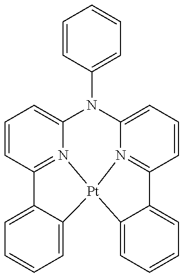 | US20060182992 US20070103060 |
| Cu complexes | 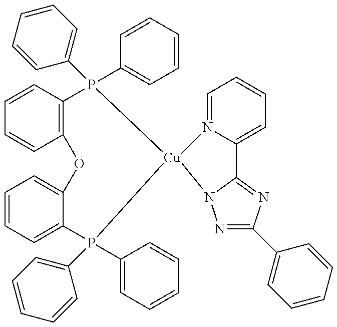 | WO2009000673 |
| | 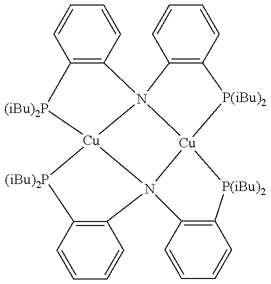 | US20070111026 |
| Gold complexes | 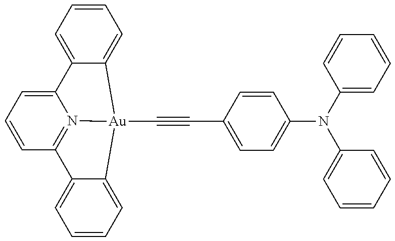 | Chem. Commun. 2906 (2005) |
| Rhenium(III) complexes | 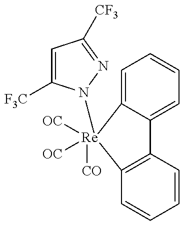 | Inorg. Chem. 42, 1248 (2003) |
| Osmium(II) complexes | 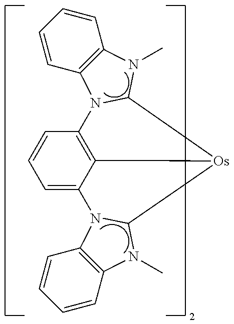 | U.S. Pat. No. 7,279,704 |
| Deuterated organometallic complexes | 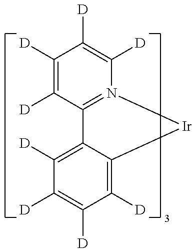 | US20030138657 |
| Organometallic complexes with two or more metal centers | 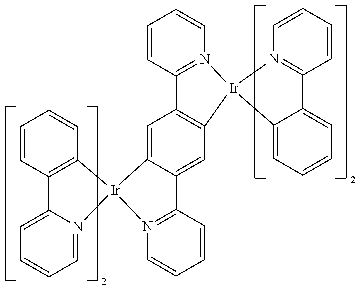 | US20030152802 |
| | 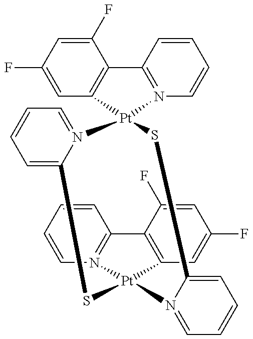 | U.S. Pat. No. 7,090,928 |

Blue dopants

| | | |
|---|---|---|
| Iridium(III) organometallic complexes | 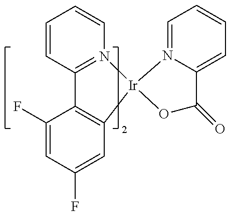 | WO2002002714 |
| | 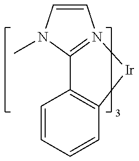 | WO2006009024 |
| | 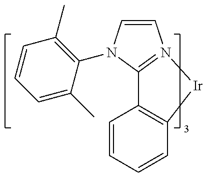 | US20060251923 US20110057559 US20110204333 |
| | 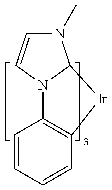 | U.S. Pat. No. 7,393,599, WO2006056418, US20050260441, WO2005019373 |
| | 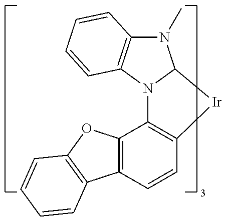 | U.S. Pat. No. 7,534,505 |
| | 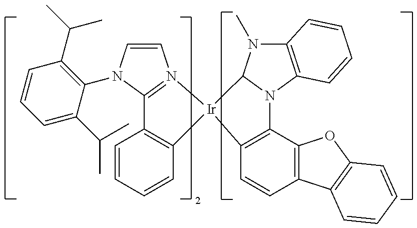 | WO2011051404 |
| | 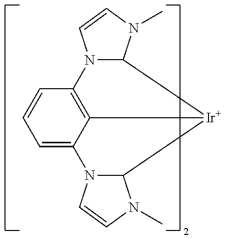 | U.S. Pat. No. 7,445,855 |
| | 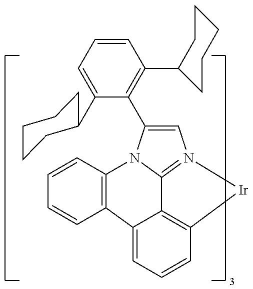 | US20070190359, US20080297033 US20100148663 |
| | 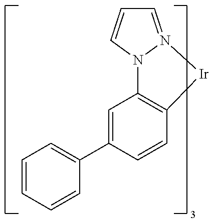 | U.S. Pat. No. 7,338,722 |
| | 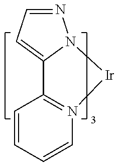 | US20020134984 |
| | 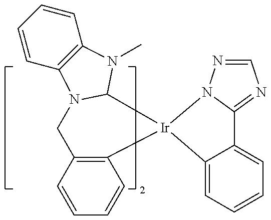 | Angew. Chem. Int. Ed. 47, 1 (2008) |
| | 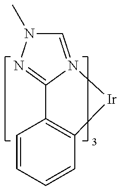 | Chem. Mater. 18, 5119 (2006) |
| | 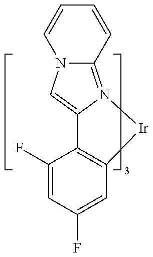 | Inorg. Chem. 46, 4308 (2007) |
| | 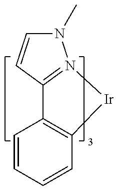 | WO2005123873 |
| | 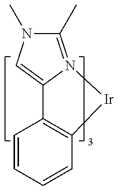 | WO2005123873 |
| | 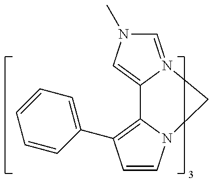 | WO2007004380 |
| | 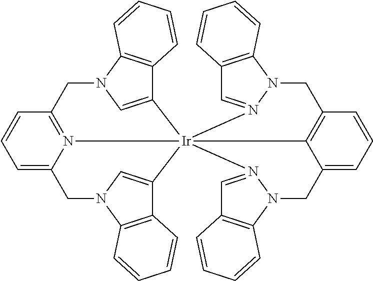 | WO2006082742 |
| Osmium(II) complexes | 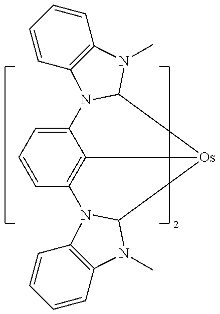 | U.S. Pat. No. 7,279,704 |
| | 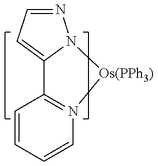 | Organometallics 23, 3745 (2004) |
| Gold complexes | 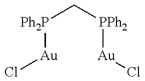 | Appl. Phys. Lett. 74, 1361 (1999) |
| Platinum(II) complexes | 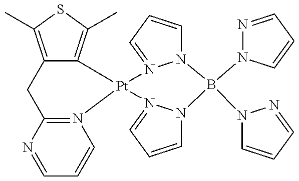 | WO2006098120, WO2006103874 |
| Pt tetradentate complexes with at least one metal-carbene bond | 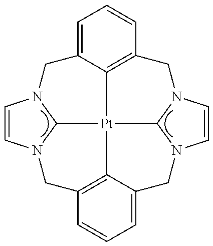 | U.S. Pat. No. 7,655,323 |

Exciton/hole blocking layer materials

| | | |
|---|---|---|
| Bathocuprine compounds (e.g., BCP, BPhen) | 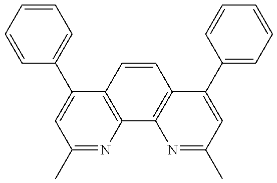 [SMILES: Cc1cc(-c2ccccc2)c2ccc3c(-c4ccccc4)cc(C)nc3c2n1] | Appl. Phys. Lett. 75, 4 (1999) |
| | 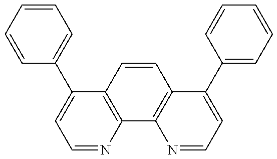 [SMILES: c1ccc(-c2ccnc3c2ccc2c(-c4ccccc4)ccnc23)cc1] | Appl. Phys. Lett. 79, 449 (2001) |
| Metal 8-hydroxyquinolates (e.g., BAlq) | 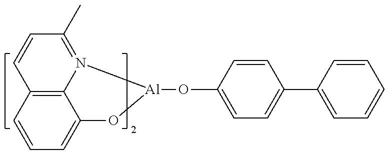 | Appl. Phys. Lett. 81, 162 (2002) |
| 5-member ring electron deficient heterocycles such as triazole, oxadiazole, imidazole, benzoimidazole | 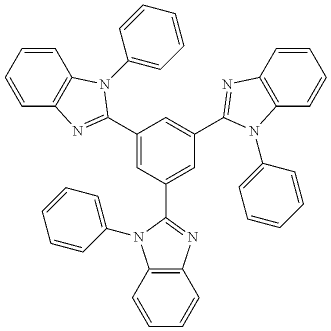 [SMILES: c1ccc(-n2c(-c3cc(-c4nc5ccccc5n4-c4ccccc4)cc(-c4nc5ccccc5n4-c4ccccc4)c3)nc3ccccc32)cc1] | Appl. Phys. Lett. 81, 162 (2002) |
| Triphenylene compounds | 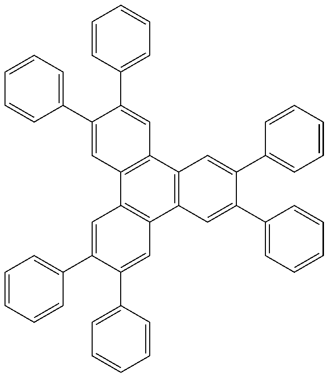 [SMILES: c1ccc(-c2cc3c4cc(-c5ccccc5)c(-c5ccccc5)cc4c4cc(-c5ccccc5)c(-c5ccccc5)cc4c3cc2-c2ccccc2)cc1] | US20050025993 |
| Fluorinated aromatic compounds | 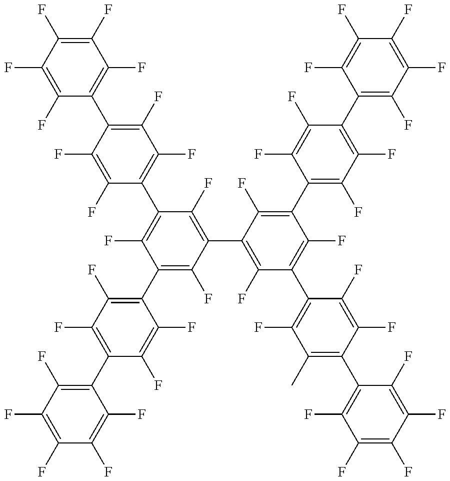 [SMILES: Cc1c(F)c(-c2c(F)c(-c3c(F)c(F)c(-c4c(F)c(F)c(F)c(F)c4F)c(F)c3F)c(F)c(-c3c(F)c(-c4c(F)c(F)c(-c5c(F)c(F)c(F)c(F)c5F)c(F)c4F)c(F)c(-c4c(F)c(F)c(-c5c(F)c(F)c(F)c(F)c5F)c(F)c4F)c3F)c2F)c(F)c(F)c1-c1c(F)c(F)c(F)c(F)c1F] | Appl. Phys. Lett. 79, 156 (2001) |
| Phenothiazine-S- oxide | 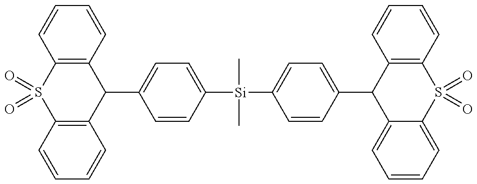 [SMILES: C[Si](C)(c1ccc(C2c3ccccc3S(=O)(=O)c3ccccc32)cc1)c1ccc(C2c3ccccc3S(=O)(=O)c3ccccc32)cc1] | WO2008132085 |
| Silylated five- membered nitrogen, oxygen, sulfur or phosphorus dibenzoheterocycles | 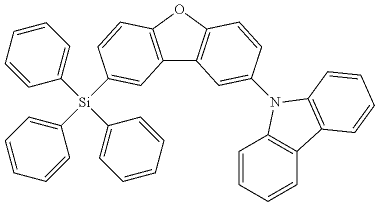 [SMILES: c1ccc([Si](c2ccccc2)(c2ccccc2)c2ccc3oc4ccc(-n5c6ccccc6c6ccccc65)cc4c3c2)cc1] | WO2010079051 |
| Aza-carbazole | 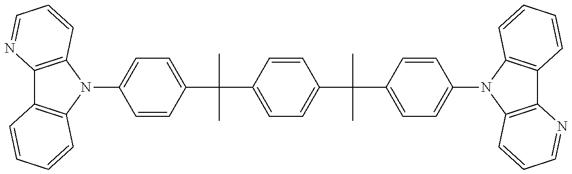 [SMILES: CC(C)(c1ccc(-n2c3ccccc3c3ncccc32)cc1)c1ccc(C(C)(C)c2ccc(-n3c4ccccc4c4ncccc43)cc2)cc1] | US20060121308 |

Electron transporting materials

| | | |
|---|---|---|
| Anthracene- benzoimidazole compounds | 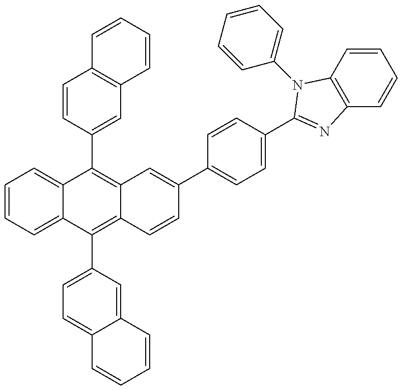 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1] | WO2003060956 |
| | 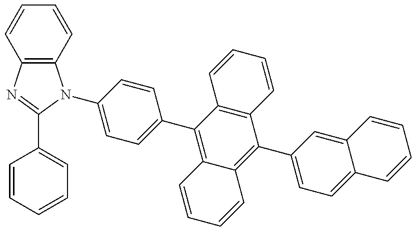 [SMILES: c1ccc(-c2nc3ccccc3n2-c2ccc(-c3c4ccccc4c(-c4ccc5ccccc5c4)c4ccccc34)cc2)cc1] | US20090179554 |
| Aza triphenylene derivatives | 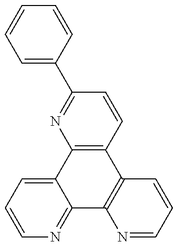 [SMILES: c1ccc(-c2ccc3c4cccnc4c4ncccc4c3n2)cc1] | US20090115316 |
| Anthracene- benzothiazole compounds | 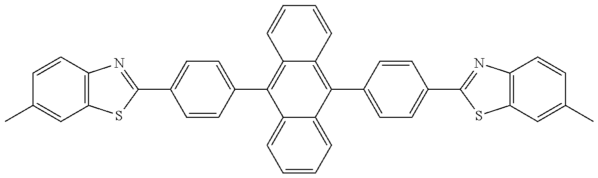 | Appl. Phys. Lett. 89, 063504 (2006) |
| Metal 8-hydroxyquinolates (e.g., Alq₃, Zrq₄) | 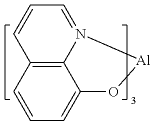 | Appl. Phys. Lett. 51, 913 (1987) U.S. Pat. No. 7,230,107 |
| Metal hydroxybenoquinolates | 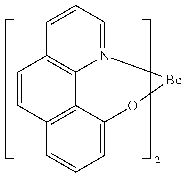 | Chem. Lett. 5, 905 (1993) |
| Bathocuprine compounds such as BCP, BPhen, etc | 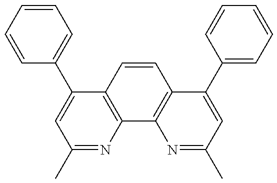 [SMILES: Cc1cc(-c2ccccc2)c2ccc3c(-c4ccccc4)cc(C)nc3c2n1] | Appl. Phys. Lett. 91, 263503 (2007) |
| | 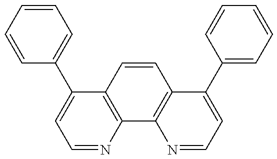 [SMILES: c1ccc(-c2ccnc3c2ccc2c(-c4ccccc4)ccnc23)cc1] | Appl. Phys. Lett. 79, 449 (2001) |
| 5-member ring electron deficient heterocycles (e.g., triazole, oxadiazole, imidazole, benzoimidazole) | 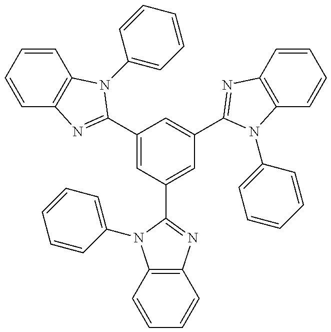 [SMILES: c1ccc(-n2c(-c3cc(-c4nc5ccccc5n4-c4ccccc4)cc(-c4nc5ccccc5n4-c4ccccc4)c3)nc3ccccc32)cc1] | Appl. Phys. Lett. 74, 865 (1999) |
| | 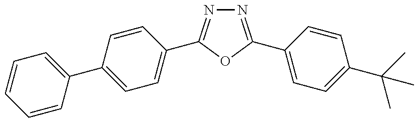 [SMILES: CC(C)(C)c1ccc(-c2nnc(-c3ccc(-c4ccccc4)cc3)o2)cc1] | Appl. Phys. Lett. 55, 1489 (1989) |
| | 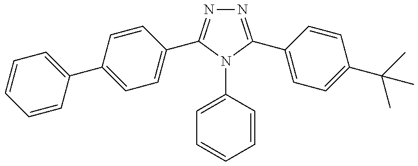 [SMILES: CC(C)(C)c1ccc(-c2nnc(-c3ccc(-c4ccccc4)cc3)n2-c2ccccc2)cc1] | Jpn. J. Apply. Phys. 32, L917 (1993) |
| Silole compounds | 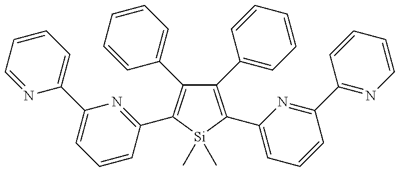 [SMILES: C[Si]1(C)C(c2cccc(-c3ccccn3)n2)=C(c2ccccc2)C(c2ccccc2)=C1c1cccc(-c2ccccn2)n1] | Org. Electron. 4, 113 (2003) |
| Arylborane compounds | 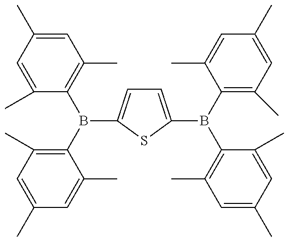 | J. Am. Chem. Soc. 120, 9714 (1998) |
| Fluorinated aromatic compounds | 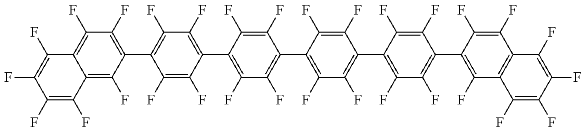 [SMILES: Fc1c(F)c(-c2c(F)c(F)c(-c3c(F)c(F)c4c(F)c(F)c(F)c(F)c4c3F)c(F)c2F)c(F)c(F)c1-c1c(F)c(F)c(-c2c(F)c(F)c(-c3c(F)c(F)c4c(F)c(F)c(F)c(F)c4c3F)c(F)c2F)c(F)c1F] | J. Am. Chem. Soc. 122, 1832 (2000) |
| Fullerene (e.g., C60) | 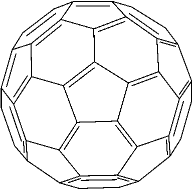 | US20090101870 |
| Triazine complexes | 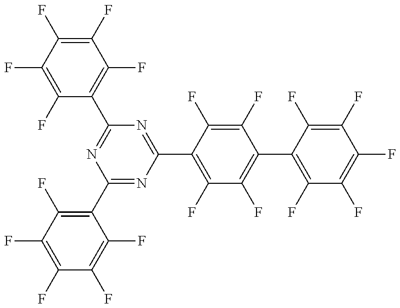 [SMILES: Fc1c(F)c(F)c(-c2nc(-c3c(F)c(F)c(F)c(F)c3F)nc(-c3c(F)c(F)c(-c4c(F)c(F)c(F)c(F)c4F)c(F)c3F)n2)c(F)c1F] | US20040036077 |
| Zn (N\hat{ }N) complexes | 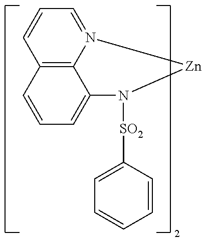 | U.S. Pat. No. 6,528,187 |

### EXAMPLES

### Example 1—Computational Examples

DFT calculations were performed for certain example compounds and comparative compounds. The example compounds and comparative compounds are shown on the following page. In certain models, a hot, Host 1, was used, which is also shown.

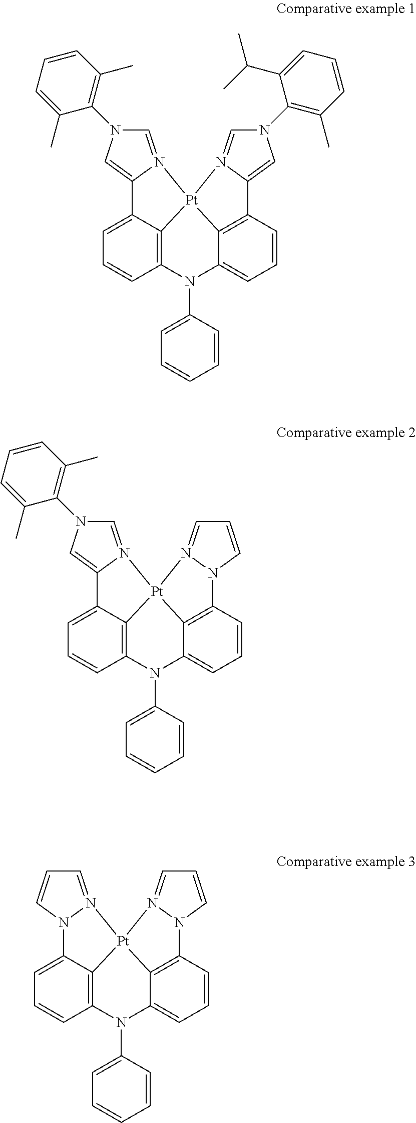

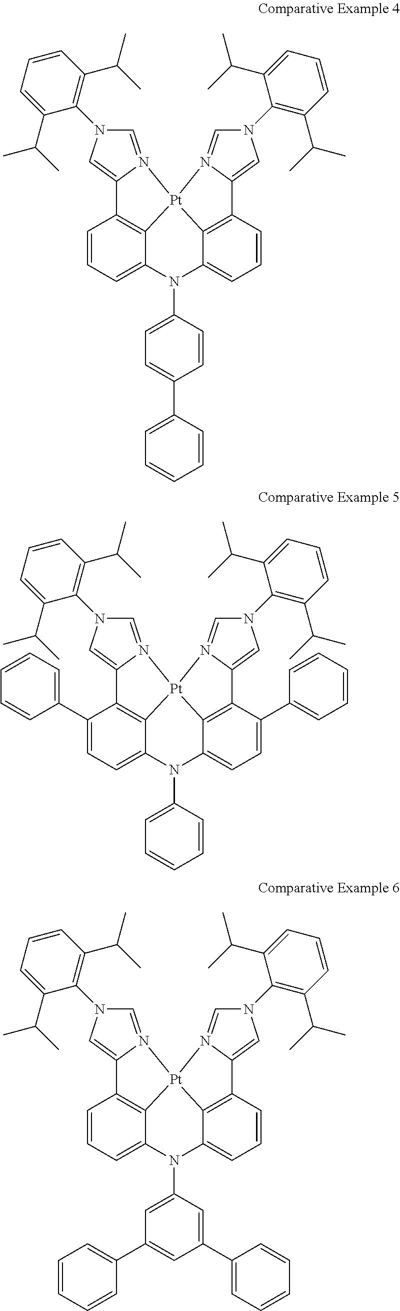

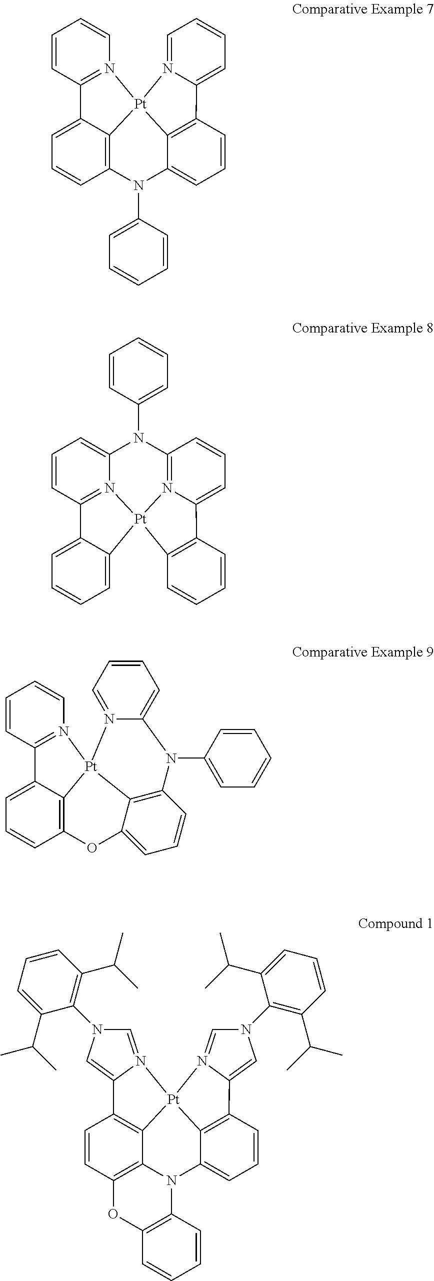

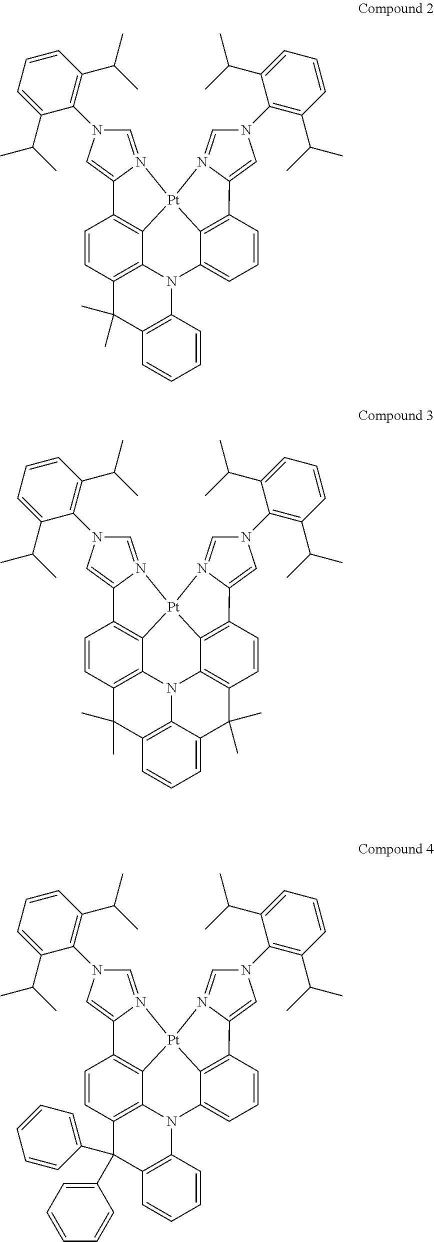

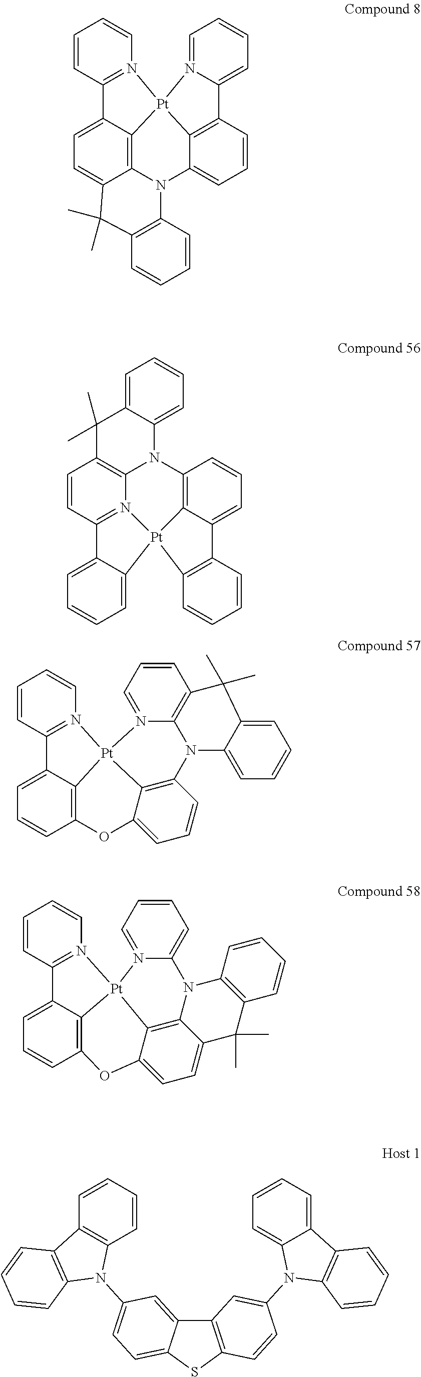

Geometry optimization calculations were performed within the Gaussian 09 software package using the B3LYP hybrid functional and CEP-31g effective core potential basis set. Complexes were optimized as both ground state singlets and triplets. Three bonds strengths of interest were examined: N-aryl, N-phenyl, and N-Phenyl2, the identities of which are shown in Structure A atop the following page.

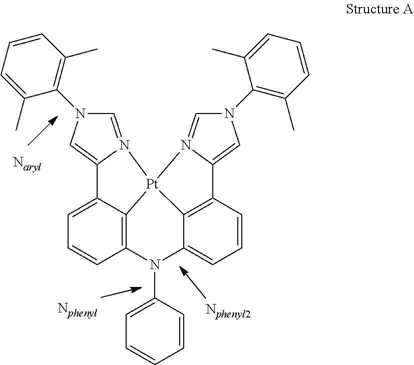

Bond strength calculations were executed at the same level of theory by two approaches which were dependent on either (a) creating two fragments or (b) breaking a bond that does not cause fragmentation.

Fragmentation of the phenyl group from the bridging nitrogen (Nphenyl) results in the transition metal fragment in a doublet spin state and the phenyl group also in a doublet spin state. The complete fragmentation is only observed for Comparative Examples 4-6, where the N-phenyl bond is not tethered. For these complexes, the Nphenyl fragment can be completely removed whereas for Compound 1-4, the phenyl fragment remains bound to the complex on one or both sides. For complexes that do not fragment the phenyl bonded to the bridging nitrogen both singlet→singlet and triplet→triplet spin states bond strength energies were calculated. The results are shown below in TABLE 2.

TABLE 2

| | | N-Phenyl | N-Aryl | N-Phenyl-2 | | Device Lifetime |
|---|---|---|---|---|---|---|
| | Calc | Bond Strength, | Bond Strength, | Bond Strength, | Weakest | (relative to |
| | T1 | singlet/triplet | singlet/triplet | singlet/triplet | bond | comparative |
| Compound | (nm) | (kcal/mol) | (kcal/mol) | (kcal/mol) | (kcal/mol) | example 1) |
| Comparative | 467 | 66.82/8.02 | 74.08/15.28 | 85.89/27.09 | 8.02 | 1 |
| Example 1 | | | | | | |
| Comparative | 502 | 67.69/13.35 | 77.15/22.81 | | 13.35 | 10 |
| Example 2 | | | | | | |
| Comparative | 508 | 68.79/15.32 | n/a | | 15.32 | 100 |
| Example 3 | | | | | | |
| Comparative | 467 | 66.92/8.17 | 74.15/15.40 | 84.98/26.23 | 8.17 | |
| Example 4 | | | | | | |
| Comparative | 475 | 66.35/10.99 | 75.29/19.93 | 85.41/30.06 | 10.99 | |
| Example 5 | | | | | | |
| Comparative | 467 | 66.40/7.82 | 74.21/15.63 | 86.00/27.42 | 7.82 | |
| Example 6 | | | | | | |
| Comparative | | 67.86/25.67 | | | 25.67 | |
| Example 7 | | | | | | |
| Comparative | | 69.19/15.01 | | | 15.01 | |
| Example 8 | | | | | | |
| Comparative | | 67.33/14.26 | | | 14.26 | |
| Example 9 | | | | | | |
| Compound 1 | 475 | 70.31/11.52 | 75.84/17.05 | 75.73/16.95 | 11.52 | |
| Compound 2 | 464 | 73.10/12.36 | 75.57/14.83 | 81.82/21.08 | 12.36 | |
| Compound 3 | 466 | 62.84/5.22* | 71.73/14.10 | 83.04/25.42 | 14.10 | |
| Compound 4 | 464 | 78.26/17.70 | 76.56/16.00 | 83.92/23.36 | 16.00 | |
| Compound 8 | | 73.59/29.07 | | | 29.07 | |
| Compound 56 | | 75.16/21.18 | | | 21.18 | |
| Compound 57 | | 76.07/22.91 | | | 22.91 | |
| Compound 58 | | 77.67/24.97 | | | 24.97 | |

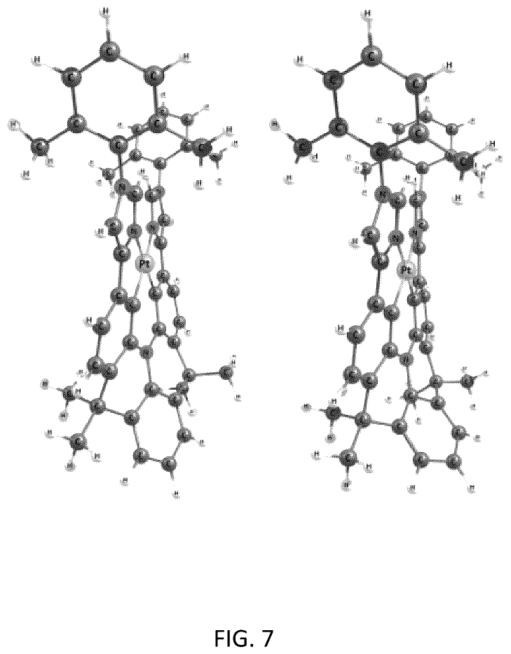

As shown in TABLE 2, calculations indicate that linking the phenyl in the N-phenyl position to the phenyl of the phenlyimidazole ligand increases the N-phenyl bond strength. In the triplet state, Comparative Example 1 has an N-phenyl bond strength of 8.02 kcal/mole. Comparative Examples 4 and 6, without tethering substitutions are found to have similar N-phenyl bond strength compared to Comparative Example 1. Compound 2 is shown to have a stronger N-phenyl bond of 10.99 kcal/mol, however, the triplet energy of 475 nm is lower than Comparative Example 1. Tethered examples, Compounds 1-4 are found to have stronger N-phenyl bonds while in several cases retaining the desirable high triplet energy. A special case is found for Compound 3, which is tethered by geminal dimethyl groups on both sides. As shown in the table, designated by “*”, these substitutions are calculated to have a large impact on the N-phenyl bond strength. Linking the phenyl group to the complex on both sides prevents the phenyl from twisting or moving out of the bonding position. Optimization results in a distorted geometry of Compound 3, such that the phenyl is not directly lined up with the nitrogen and the N-phenyl bond. The distortion results in a relatively small calculated energy difference of 5.22 kcal/mol for the N-phenyl bond strength of Compound 3. However, the N-phenyl bond is reformed, so the small difference in energy is related to the slight geometry difference, not a broken bond. The calculated geometric distortion for Compound 3 is shown in FIG. 7. Thus, tethering (or bridging) the phenyl group on both sides retains the N-phenyl bond and shifts the lowest bond strength to the N-aryl bond. In addition the other structures, Compound 1, 2 and 4, are found to have greater N-phenyl bond strengths compared to Comparative Example 1.

Calculating the Naryl bond strengths was done by removing the dimethylphenyl group and separately calculating the energies of the doublet complex and dimethylphenyl. There are no major differences in the N-aryl bond strengths besides the differing ground state triplet energies between the complexes.

Finally, calculations were performed on the N-phenyl-2 bond in which the bridging N atom is detached from the phenyl of the phenylimidazole ligand. This bond is calculated to be the strongest bond of the three investigated except for complex Compound 1. The N-phenyl-2 bond strength is calculated to be a mere 0.1 kcal/mol weaker than the N-aryl bond for complex Compound 1. In all cases, the N-phenyl-2 bond is never calculated to be the weakest bond of the complex. This suggests that the breaking the N-phenyl-2 bond is not a significant source of decomposition. In addition, Compound 8, 56, 57, and 58 further demonstrate the versatility of this approach. In each case the N-aryl bond strength is calculated to be greater than the corresponding untethered comparative example, Compartative Example 7, 8 and 9.

### Example 2—MALDI-TOF Fragmentation

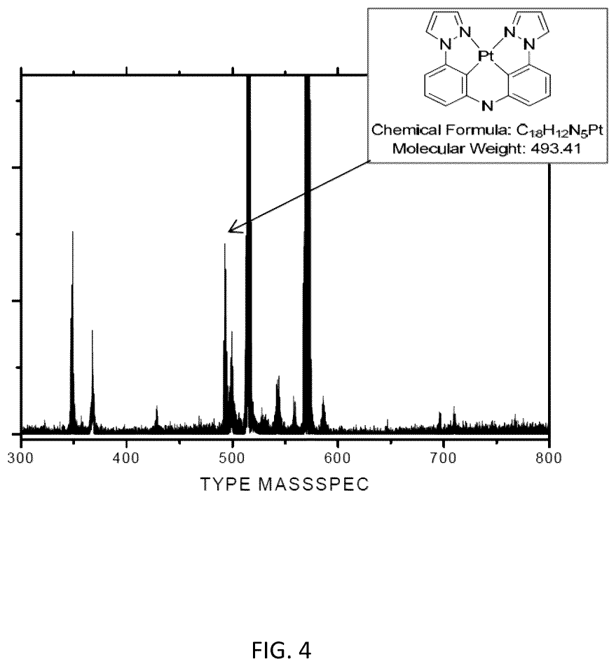

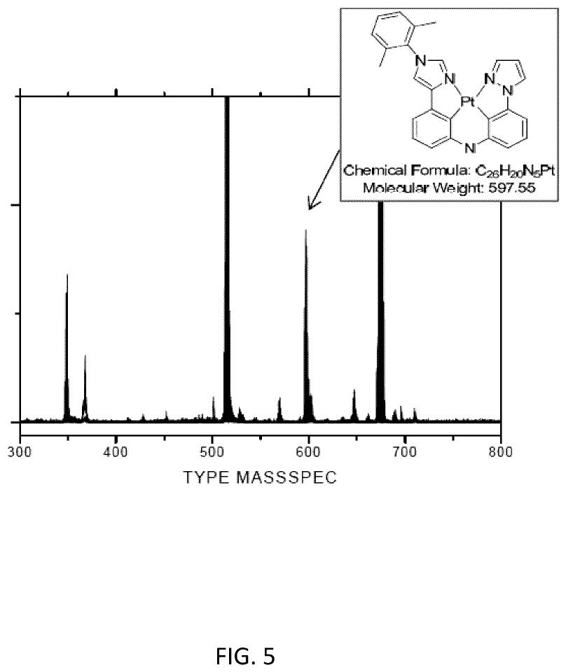

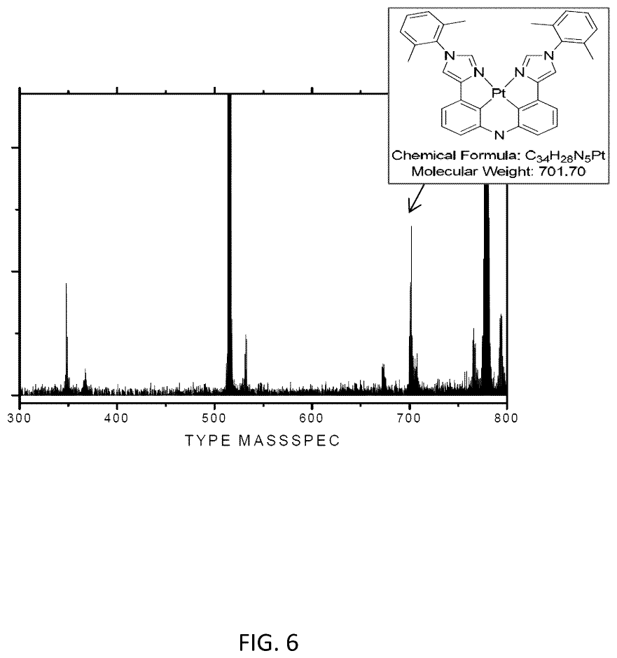

The relative instability of the N—C ring bond is demonstrated experimentally by excited state fragmentation patterns observed in a MALDI mass spectrometer. Host 1 and Comparative Examples 1-3 at an approximate 20 wt % ratio were dissolved in dichloromethane and spot cast on an Applied Biosystems Voyager DE-STR MALDI sample target plate. The samples were analyzed in the positive mode. FIGS. 4-6 show that there is a major fragment that results from the loss of the N-phenyl ring, i.e. N—C ring bond breakage. In each case, it is found that the broken N—C bond is an abundant fragment associated with the dopant.

Without being bound to any theory, it is believed that linking or tethering (or bridging) the C-Ring back to the complex will result in an improvement in stability particularly for phosphorescent metal complexes with bridging aryl amine substitutions.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A compound having a structure of Formula (VI), 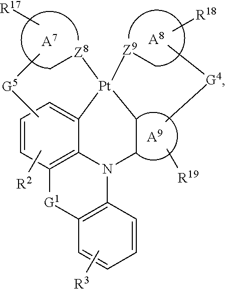
wherein,
rings A⁷, A⁸, and A⁹ are independently five- or six-membered carbocyc;ic or heterocyclic aromatic rings having 0-3 nitrogen atoms and 0-1 additional heteroatoms selected from the group consisting of oxygen, sulfur, and selenium;
Z⁸ and Z⁹ are independently carbon or nitrogen;
G¹ is O or CR⁴R⁵;
R² represents mono-, di-, or tri-substitution, wherein each R² is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R² may optionally combine to form a ring, which can be further substituted;
R³ represents mono-, di-, tri-, or tetra-substitution, wherein each R³ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R³ may optionally combine to form a ring, which can be further substituted;
R⁴ and R⁵ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof;
R⁴ and R⁵ may optionally combine to form a ring, which can be further substituted;
any of R⁴ or R⁵ may optionally combine with any R² or R³ to form a ring system, which can be further substituted;
G⁴ is oxygen, sulfur, CR²⁰R^{20a}, SiR²⁰R^{20a}, or NR²⁰;
each R²⁰ and R^{20a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and
R²⁰ and R^{20a} may optionally combine with each other or with any one R¹⁸ or R¹⁹ to form a ring system, which can be further substituted;
G⁵ is oxygen, sulfur, CR²¹R^{21a}, SiR²¹R^{21a}, or NR²¹;
each R²¹ and R^{21a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein
R²¹ and R^{21a} can be combine with each other or with any one R² or R¹⁷ to form a ring system, which can be further substituted;
R¹⁷ and R¹⁸ represent mono-, di-, tri-, or tetra-substitution, wherein each R¹⁷ or R¹⁸ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹⁷ or any two adjacent R¹⁸ may optionally combine to form a ring, which can be further substituted;
R¹⁹ represents mono-, di-, or tri-substitution, wherein each R¹⁹ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹⁹ can combine to form a ring, which can be further substituted; and
any R³ may optionally combine with any R¹⁹ to form a ring system, which can be further substituted.

2. The compound of claim 1, wherein G⁴ is selected from CR²⁰R^{20a}, SiR²⁰R^{20a}, or NR²⁰, and G⁵ is selected from CR²¹R^{21a}, SiR²¹R^{21a}, and NR²¹.

3. The compound of claim 1, wherein G⁴ is NR²⁰ and G⁵ is NR²¹.

4. The compound of claim 3, wherein R²¹ is combined with one R² to form a ring system, which can be further substituted.

5. The compound of claim 3, wherein R²¹ is combined with one R¹⁷ to form a ring system, which can be further substituted.

6. The compound of claim 3, wherein R²¹ is aryl and is bonded to the ring substituted by R² by a direct bond to form a ring system, which can be further substituted.

7. The compound of claim 6, wherein R²¹ is phenyl.

8. The compound of claim 7, wherein R²⁰ is aryl and is combined with an R¹⁹ to form a ring system.

9. The compound of claim 8, wherein R²⁰ is phenyl.

10. The compound of claim 1, wherein Z⁸ and Zº are nitrogen.

11. The compound of claim 10, wherein A⁷ is a 5-membered ring, A⁸ is a 6-membered ring, and A⁹ is phenyl.

12. The compound of claim 10, wherein A⁷ is a 6-membered ring, A⁸ is a 6-membered ring, and A⁹ is phenyl.

13. A first device comprising a first organic light emitting device, which further comprises:
an anode;
a cathode; and
an organic layer disposed between the anode and the cathode, which comprises a compound having a structure of Formula (VI), 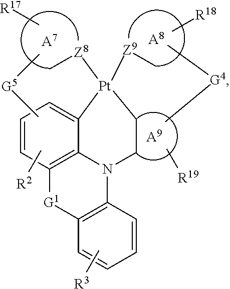
wherein:
rings A⁷, A⁸, and A⁹ are independently five- or six-membered carbocyc;ic or heterocyclic aromatic rings having 0-3 nitrogen atoms and 0-1 additional heteroatoms selected from the group consisting of oxygen, sulfur, and selenium;
Z⁸ and Zº are independently carbon or nitrogen;
G¹ is O or CR⁴R⁵;
R² represents mono-, di-, or tri-substitution, wherein each R² is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R² may optionally combine to form a ring, which can be further substituted;
R³ represents mono-, di-, tri-, or tetra-substitution, wherein each R³ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R³ may optionally combine to form a ring, which can be further substituted;
R⁴ and R⁵ are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof;
R⁴ and R⁵ may optionally combine to form a ring, which can be further substituted;
any of R⁴ or R⁵ may optionally combine with any R² or R³ to form a ring system, which can be further substituted;
G⁴ is oxygen, sulfur, CR²⁰R^{20a}, SiR²⁰R^{20a}, or NR²⁰;
each R²⁰ and R^{20a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and
R²⁰ and R^{20a} may optionally combine with each other or with any one R¹⁸ or R¹⁹ to form a ring system, which can be further substituted;
G⁵ is oxygen, sulfur, CR²¹R^{21a}, SiR²¹R^{21a}, or NR²¹;
each R²¹ and R^{21a} is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein R²¹ and R^{21a} can be combine with each other or with any one R² or R¹⁷ to form a ring system, which can be further substituted;
R¹⁷ and R¹⁸ represent mono-, di-, tri-, or tetra-substitution, wherein each R¹⁷ or R¹⁸ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹⁷ or any two adjacent R¹⁸ may optionally combine to form a ring, which can be further substituted;
R¹⁹ represents mono-, di-, or tri-substitution, wherein each R¹⁹ is selected independently from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, and wherein any two adjacent R¹⁹ can combine to form a ring, which can be further substituted; and
any R³ may optionally combine with any R¹⁹ to form a ring system, which can be further substituted.

14. The first device of claim 13, wherein the first device is a consumer product, an organic light-emitting device, or a lighting panel.

15. The first device of claim 13, wherein the organic layer is an emissive layer and the compound is an emissive dopant.

16. The first device of claim 13, wherein the organic layer is an emissive layer and the compound is a non-emissive dopant.

17. The first device of claim 13, wherein the organic layer further comprises a host, and the host comprises a compound selected from the group consisting of: carbazole, dibenzothiophene, dibenzofuran, dibenzoselenophene, azacarbazole, aza-dibenzothiophene, aza-dibenzofuran, and aza-dibenzoselenophene.

18. The first device of claim 13, wherein the organic layer further comprises a host, and the host is selected from the group consisting of: 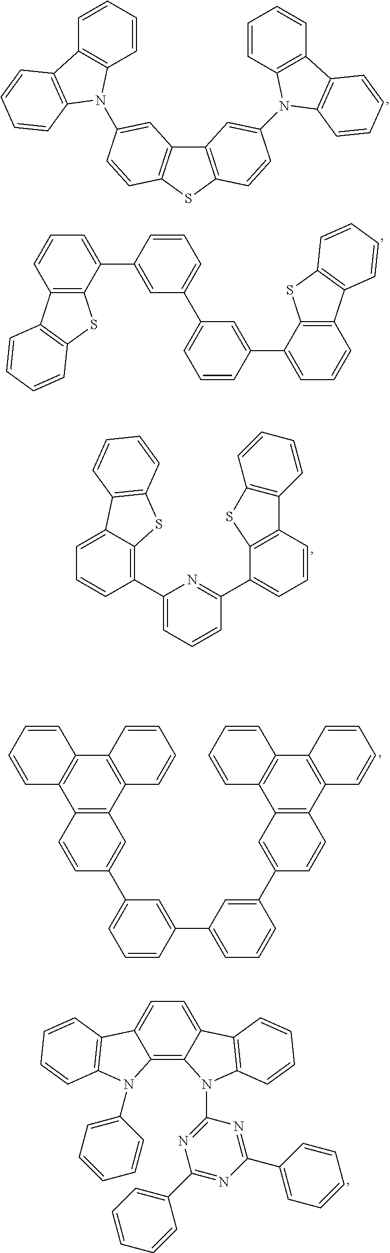 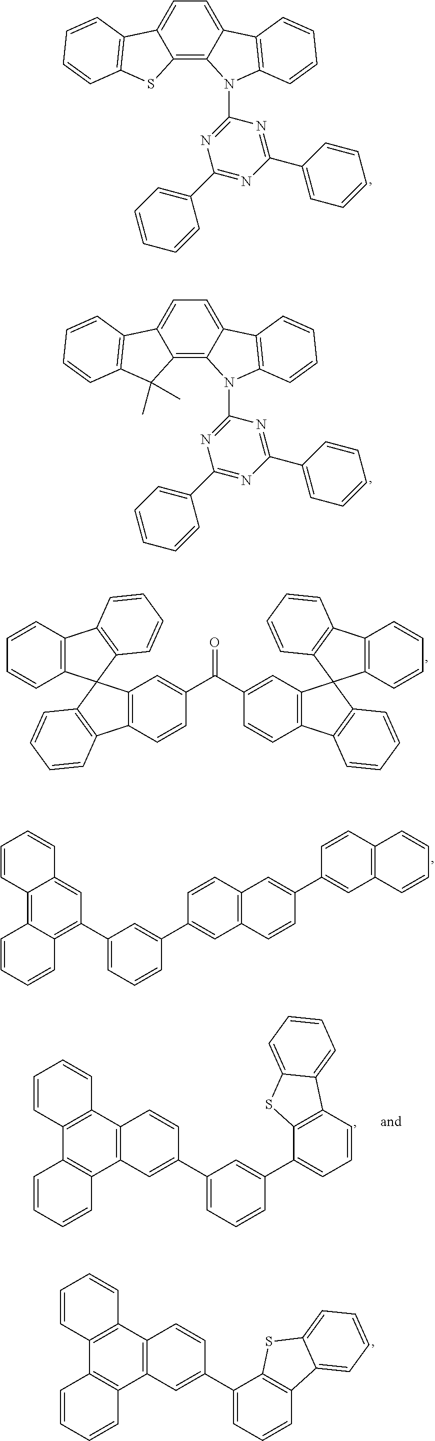
and combinations thereof.

19. The first device of claim 17, wherein the organic layer further comprises a host, and the host comprises a metal complex.

20. A first device comprising a first organic light emitting device, which further comprises:
an organic layer disposed between the anode and the cathode, which comprises the compound of claim 1.
